(19) United States
(12) Patent Application Publication
(10) Pub. No.: US 2020/0203243 A1
(43) Pub. Date: Jun. 25, 2020

(54) UNIVERSAL LEADED/LEADLESS CHIP SCALE PACKAGE FOR MICROELECRONIC DEVICES

(71) Applicant: Texas Instruments Incorporated, Dallas, TX (US)

(72) Inventor: Sreenivasan K. Koduri, Allen, TX (US)

(73) Assignee: Texas Instruments Incorporated, Dallas, TX (US)

(21) Appl. No.: 16/225,164

(22) Filed: Dec. 19, 2018

(51) Int. Cl. H01L 23/31; H01L 25/065; H01L 23/495; H01L 23/00; H01L 21/56

(52) U.S. Cl. CPC H01L 23/3114; H01L 25/0655; H01L 23/49555; H01L 24/32; H01L 21/56; H01L 24/49; H01L 24/73; H01L 24/43; H01L 24/09

(57) ABSTRACT

A microelectronic device, in a leaded/leadless chip scale package, has a die and intermediate pads located adjacent to the die. The intermediate pads are free of photolithographically-defined structures. Wire bonds connect the die to the intermediate pads. An encapsulation material at least partially surrounds the die and the wire bonds, and contacts the intermediate pads. Package leads, located outside of the encapsulation material, are attached to the intermediate pads. The microelectronic device is formed by mounting the die on a carrier, and forming the intermediate pads on the carrier without using a photolithographic process. Wire bonds are formed between the die and the intermediate pads. The die, the wire bonds, and the intermediate pads are covered with an encapsulation material, and the carrier is subsequently removed, exposing the intermediate pads. The package leads are attached to the intermediate pads.

### FIELD

This disclosure relates to the field of microelectronic devices. More particularly, this disclosure relates to chip scale packaging of microelectronic devices.

### BACKGROUND

Leaded packages, such as plastic dual in-line packages (PDIP) and skinny dual in-line packages (SDIP) provide reliable through-hole packages for microelectronic devices. Similarly, leadless packages, such as quad-flat no-package leads (QFN), small outline integrated circuit (SOIC), small outline transistor (SOT), thin shrink small outline package (TSSOP), and small outline no-package leads (SON), provide reliable surface mount packages for microelectronic devices. The lead frames used in leaded and leadless packages must meet several criteria to provide desired reliability. The lead frame must provide a suitable surface for wire bonding to the microelectronic device. The lead frame must have a shape and surface material suitable for adhering to the encapsulation material of the package. Meeting the criteria imposes undesirable costs on the lead frame.

### SUMMARY

The present disclosure introduces a microelectronic device having a leaded/leadless chip scale package, and a method for forming the microelectronic device. The microelectronic device includes a die, intermediate pads located adjacent to the die, and wire bonds connecting the die to the intermediate pads. The intermediate pads are free of photolithographically-defined structures. An encapsulation material at least partially surrounds the die and the wire bonds, and extends to the intermediate pads. Package leads contacting the intermediate pads are located outside of the encapsulation material.

The microelectronic device is formed by mounting the die on a carrier, and forming the intermediate pads adjacent to the die without using a photolithographic process. Wire bonds are formed between the die and the intermediate pads. The die, the wire bonds, and the intermediate pads are covered with an encapsulation material, and the carrier is subsequently removed, exposing the intermediate pads. The package leads are attached to the intermediate pads.

### BRIEF DESCRIPTION OF THE VIEWS OF THE DRAWINGS

FIG. 1A through FIG. 1L include perspectives, cross sections, and a top view of a microelectronic device having a leaded/leadless chip scale package, depicted in stages of an example method of formation.

FIG. 2A through FIG. 2K include perspectives and cross sections of a microelectronic device having a leaded/leadless chip scale package, depicted in stages of another example method of formation.

FIG. 3A through FIG. 3L include perspectives and cross sections of a microelectronic device having a leaded/leadless chip scale package, depicted in stages of a further example method of formation.

FIG. 4A through FIG. 4K include various views of a microelectronic device having a leaded/leadless chip scale package, depicted in stages of another example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

This application is related to the following U.S. patent applications: U.S. patent application Ser. No. 12/______, Attorney Docket Number TI-78741, filed concurrently with this application, U.S. patent application Ser. No. 12/______, Attorney Docket Number TI-78742, filed concurrently with this application, and U.S. patent application Ser. No. 12/______, Attorney Docket Number TI-78745, filed concurrently with this application. For applications filed concurrently with this application, with their mention in this section, these patent applications are not admitted to be prior art with respect to the present invention.

A microelectronic device has a die in a leaded/leadless chip scale package. The leaded/leadless chip scale package includes intermediate pads located adjacent to the die. The intermediate pads are free of photolithographically-defined structures. Wire bonds connect the die to the intermediate pads. An encapsulation material at least partially surrounds the die and the wire bonds, and extends to the intermediate pads. Package leads contacting the intermediate pads are located outside of the encapsulation material. For the purposes of this disclosure, a leaded/leadless chip scale package has leads which may extend away from the encapsulation material (leaded chip scale package), or leads which are substantially conformal to the encapsulation material (leadless chip scale package), and wire bonds to the intermediate pads that are formed after the die is singulated from a wafer which contained the die.

The microelectronic device is formed by mounting the die on a carrier, and forming the intermediate pads adjacent to the die without using a photolithographic process. Wire bonds are formed between the die and the intermediate pads. The die, the wire bonds, and the intermediate pads are covered with an encapsulation material. The encapsulation material extends to the intermediate pads. The carrier is subsequently removed, exposing the intermediate pads. The package leads are attached to the intermediate pads.

For the purposes of this disclosure, photolithographically-defined structures include structures which are formed by forming a layer, using a photolithographic process to form an etch mask over the layer, and removing the layer where exposed by the etch mask. Photolithographically-defined structures include structures which are formed by using a photolithographic process to form a plating mask, and plating metal in areas exposed by the plating mask. For the purposes of this disclosure, photolithographic processes include exposing photosensitive material to patterned radiation using a photomask, exposing photosensitive material to patterned radiation using a maskless light source such as a micro-mirror system, X-ray lithography, e-beam lithography, and exposing photosensitive material to patterned radiation using scanned laser lithography.

For the purposes of this disclosure, the term “wire bonding” is understood to encompass bonding with round bond wire and with ribbon wire. Furthermore, the term “wire bonding” is understood to encompass ball bonding, stitch bonding, and wedge bonding. Similarly, the term “wire bond” is understood to encompass bonds with round bond wire and ribbon wire, and encompass bonds with ball bonds, stitch bonds, and wedge bonds. The term “die” is used in this disclosure to denote a single chip or more than one chip.

It is noted that terms such as top, bottom, front, back, over, above, under, and below may be used in this disclosure. These terms should not be construed as limiting the position or orientation of a structure or element, but should be used to provide spatial relationship between structures or elements.

The terms “parallel” and “perpendicular” are used to describe spatial relationships of elements with respect to other elements. In one aspect of this disclosure, the terms “parallel” and “perpendicular” encompass spatial relationships that are parallel or perpendicular within fabrication tolerances encountered in the fabrication of the respective elements. In another aspect, the terms “parallel” and “perpendicular” encompass spatial relationships that are parallel or perpendicular within measurement tolerances encountered when measuring the spatial relationships.

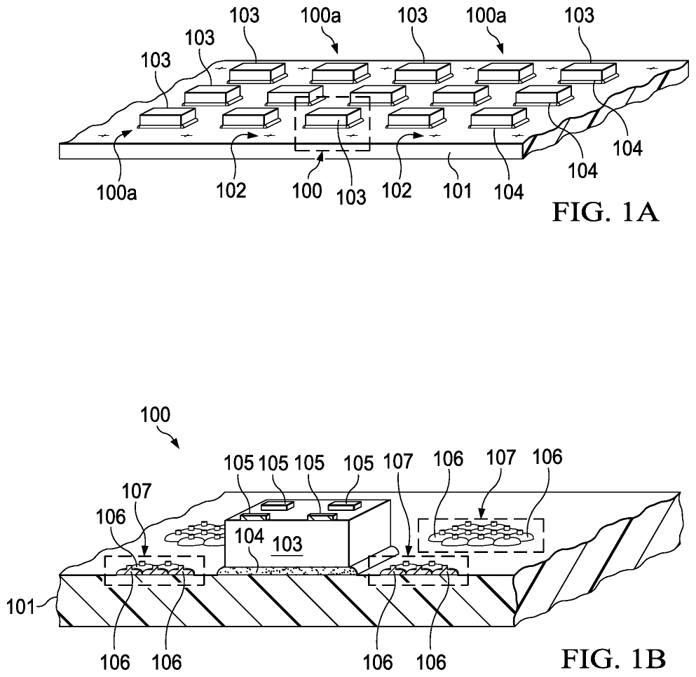

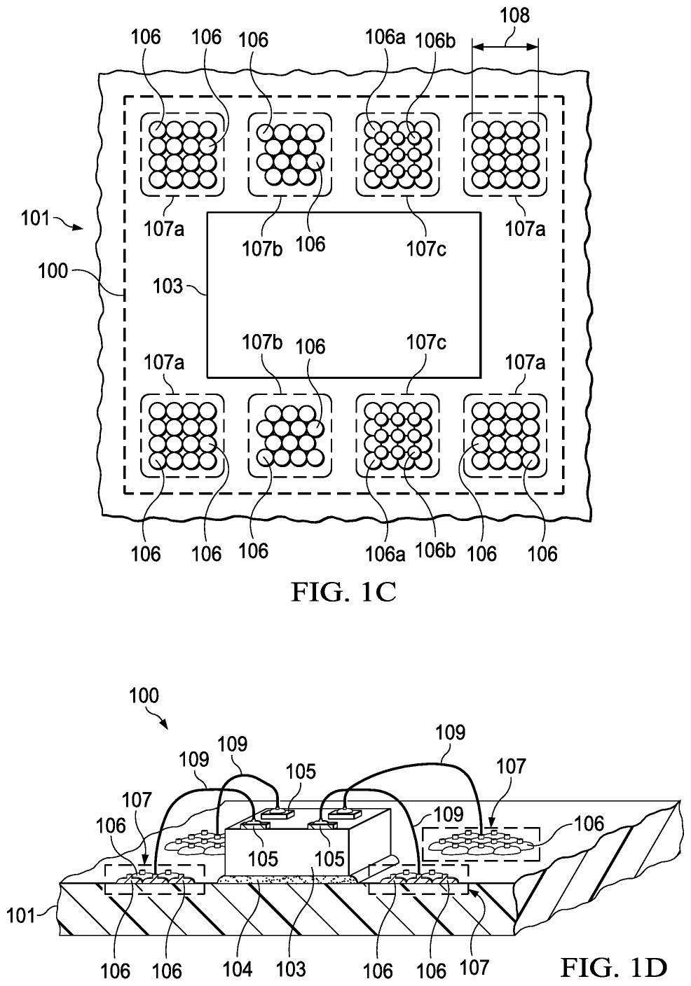

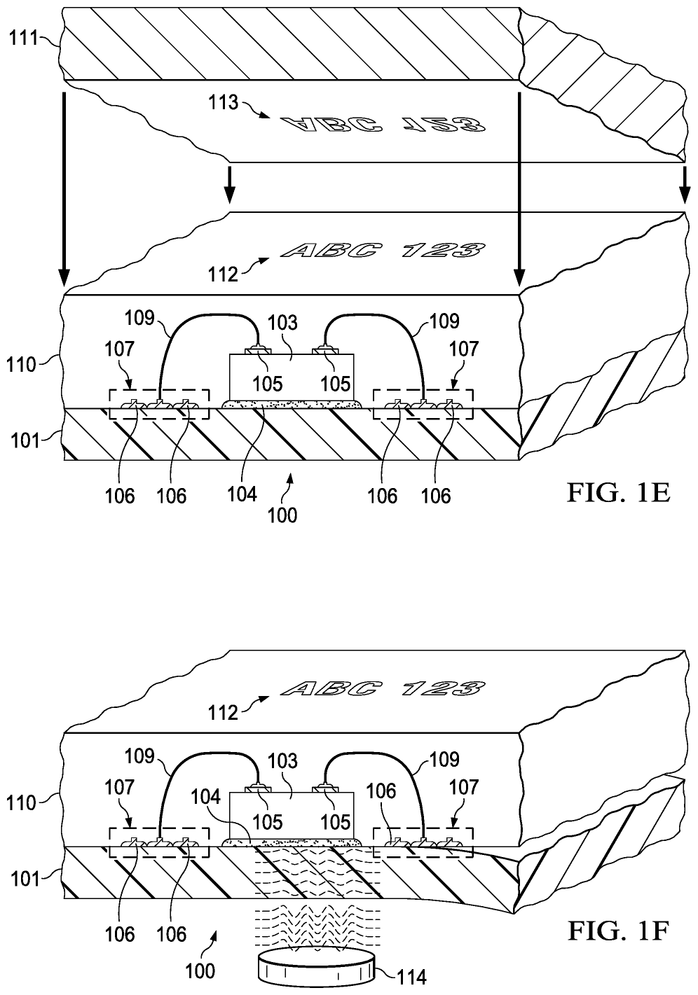

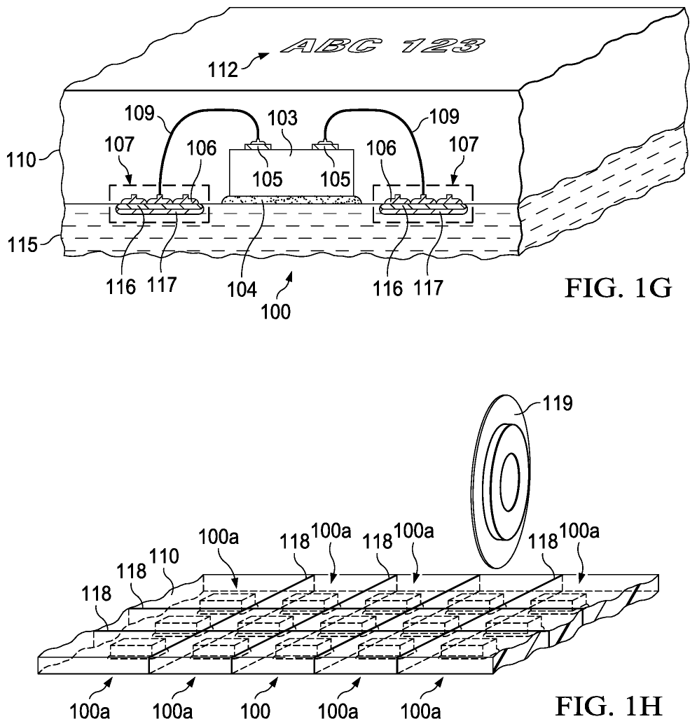

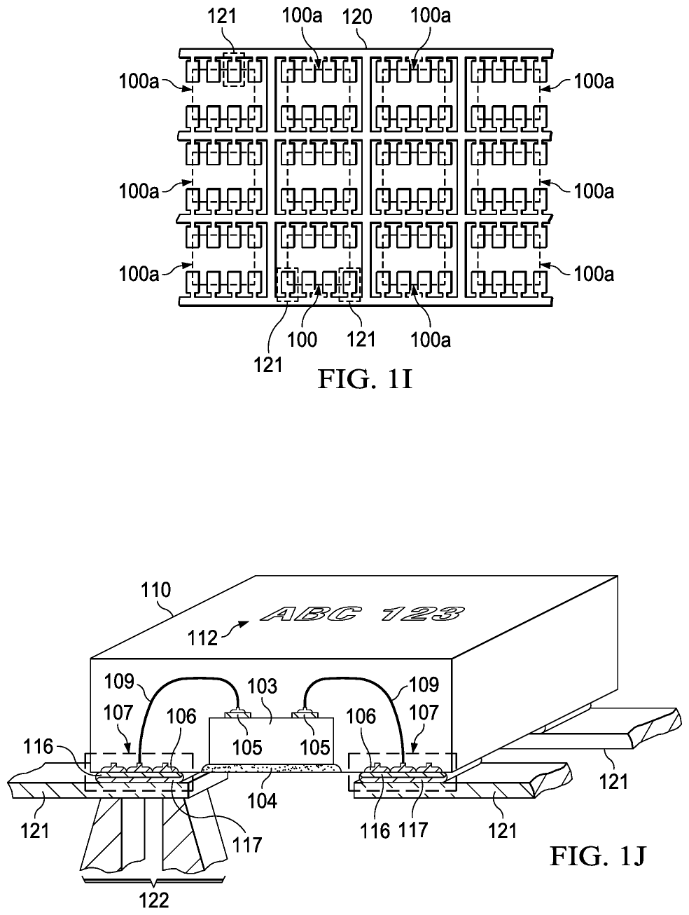

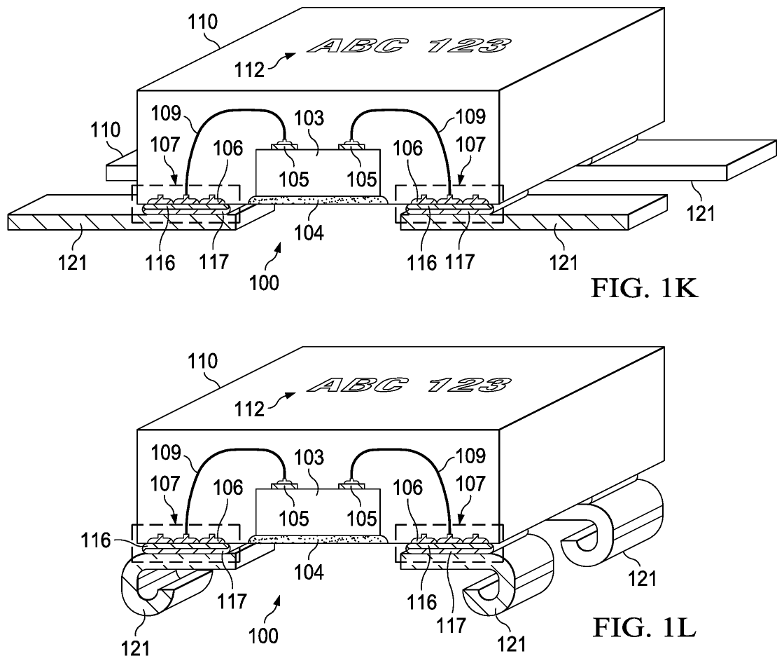

FIG. 1A through FIG. 1L include perspectives, cross sections, and a top view of a microelectronic device having a leaded/leadless chip scale package, depicted in stages of an example method of formation. Referring to FIG. 1A, formation of the microelectronic device 100 begins by providing a carrier 101. The carrier 101 includes one or more materials suitable as a substrate for forming wire bond studs, and further suitable for separation from an encapsulation material, such as epoxy. In this example, the carrier 101 may be flexible, to facilitate separation from the encapsulation material. The carrier 101 may include, for example, polycarbonate, phenolic, or acrylic material. The carrier 101 may also include particles of a hard inorganic material, such as aluminum oxide or diamond, to provide increased hardness. The carrier 101 may have a laminated structure, with a thin, hard surface layer of glass or metal, attached to a flexible substrate. Other compositions and structures for the carrier 101 are within the scope of this example. The carrier 101 may have alignment marks 102 to assist subsequent placement of die on the carrier 101. The carrier 101 may have a continuous, belt-like configuration, or may have a flat rectangular configuration.

Multiple die 103 are attached to the carrier 101, in this example. One of the die 103 is attached to the carrier 101 in an area for the microelectronic device 100, and additional die 103 are attached to the carrier 101 in separate areas for additional microelectronic devices 100a. The die 103 may be manifested as integrated circuits, discrete semiconductor components, electro-optical devices, microelectrical mechanical systems (MEMS) devices, or other microelectronic die. All of the die 103 may be substantially similar devices, for example, may be instances of a particular power transistor. Alternatively, the die 103 may include more than one device type.

The die 103 may be attached to the carrier 101 by a die attach material 104, such as an adhesive. The die attach material 104 may be electrically non-conductive, to electrically isolate the die 103. The die attach material 104 may include, for example, epoxy. The die attach material 104 may include particles such as copper or silver, coated with an insulating layer, to increase thermal conductivity from the die 103 to an exterior of the microelectronic device 100.

FIG. 1B shows the microelectronic device 100 in more detail. The die 103 may have terminals 105 for electrical connections to components in the die 103. The terminals 105 may be manifested as bond pads, or may be manifested as circuit nodes, such as transistor source and drain nodes. The terminals 105 may include materials suitable for wire bonding, such as aluminum, copper, gold, or platinum.

Wire bond studs 106 are formed on the carrier 101 adjacent to the die 103, using a wire bonding process. The wire bond studs 106 may be formed by pressing a free air ball of a bond wire onto the carrier 101 with a wire bonding capillary to form a stud, and subsequently severing the bond wire proximate to the stud. The wire bond studs 106 may include primarily copper or gold, and may have some nickel or palladium from a barrier layer around the bond wire. The wire bond studs 106 are formed in contiguous groups to form initial portions of intermediate pads 107. The wire bond studs 106 in each intermediate pad 107 may optionally be connected to other wire bond studs 106 in the same intermediate pad 107 by one or more intra-pad wire bonds, as disclosed in the commonly assigned patent application having patent application Ser. No. 11/______ (Attorney Docket Number TI-78741, filed concurrently with this application, which is incorporated herein by reference but is not admitted to be prior art with respect to the present invention by its mention in this section.

FIG. 1C depicts example configurations of the wire bond studs 106 in the intermediate pads 107 of FIG. 1B. A first intermediate pad 107a may have a rectangular array of wire bond studs 106 of substantially equal sizes, as a result of being formed with equal diameter bond wire and equal force on the wire bonding capillary. Adjacent wire bond studs 106 may contact each other in the first intermediate pad 107a, to form a contiguous electrically conductive structure on the carrier 101. The rectangular array of the wire bond studs 106 in the first intermediate pad 107a may advantageously facilitate a wire bonding operation for forming the wire bond studs 106 in the first intermediate pad 107a, compared to a more complicated configuration.

A second intermediate pad 107b may have a hexagonal array of wire bond studs 106 of substantially equal sizes, as a result of being formed with equal diameter bond wire and equal force on the wire bonding capillary. Adjacent wire bond studs 106 may contact each other in the second intermediate pad 107b, to form a contiguous electrically conductive structure on the carrier 101. The hexagonal array of wire bond studs 106 in the second intermediate pad 107b may provide a denser configuration of the wire bond studs 106, which may provide a more reliable second intermediate pad 107b, compared to other configurations of wire bond studs.

A third intermediate pad 107c may have a rectangular array of first wire bond studs 106a of substantially equal first sizes, and second wire bond studs 106b of substantially equal second sizes, smaller than the first size. The second wire bond studs 106b may be disposed between the first wire bond studs 106a. Adjacent first wire bond studs 106a and second wire bond studs 106b contact each other in the third intermediate pad 107c, to form a contiguous electrically conductive structure on the carrier 101. The rectangular array of first wire bond studs 106a and second wire bond studs 106b in the third intermediate pad 107c may provide a higher fill factor of electrically conductive material in the third intermediate pad 107c, and may thus provide a more reliable third intermediate pad 107c. The rectangular array of first wire bond studs 106a and second wire bond studs 106b may be appropriate for power and ground connections to the microelectronic device 100 of FIG. 1C, which commonly conduct significantly more current than signal connections.

The first intermediate pad 107a, the second intermediate pad 107b, and the third intermediate pad 107c may each have a minimum lateral dimension 108 of 150 microns to 500 microns, to provide desired level of mechanical integrity for subsequently attaching leads, shown in FIG. 1K.

Referring to FIG. 1D, wire bonds 109 are formed by a wire bonding process to connect the die 103 to the intermediate pads 107. FIG. 1D depicts the wire bonds 109 as formed using round bond wire. Other types of bond wire, such as ribbon bond wire, are within the scope of this example. The wire bonds 109 may include, for example, copper wire, gold wire, or aluminum wire. Copper wire in the wire bonds 109 may optionally have a coating of palladium or nickel to reduce corrosion or oxidation of the copper wire. The wire bonds 109 may be formed with ball bonds on the die 103 and stitch bonds on the intermediate pads 107, as depicted in FIG. 1F. Alternatively, the wire bonds 109 may be formed with stitch bonds on the die 103 and ball bonds on the intermediate pads 107.

The wire bonds 109 may connect to the terminals 105 on the die 103, as depicted in FIG. 1D. The wire bonds 109 may connect each of the terminals 105 to a separate intermediate pad 107, as indicated in FIG. 1D. Alternatively, one of the intermediate pads 107 may be connected by the wire bonds 109 to two or more of the terminals 105. Similarly, one of the terminals 105 may be connected by the wire bonds 109 to two or more of the intermediate pads 107.

Referring to FIG. 1E, an encapsulation material 110 is formed over the die 103, the wire bonds 109, and the intermediate pads 107. The encapsulation material 110 contacts the intermediate pads 107. The encapsulation material 110 may include epoxy or other material suitable for protecting the die 103 and the wire bonds 109 from moisture and contamination. The encapsulation material 110 does not need to adhere to a lead frame, and so may optionally be free of adhesion promoters and other additives which are used to provide reliable adhesion to leads frames of chip carriers. The encapsulation material 110 may thus be less expensive, advantageously reducing a material cost of the microelectronic device 100. The encapsulation material 110 may be formed by using a press mold 111; the press mold 111 is removed after the encapsulation material 110 is formed. Alternatively, the encapsulation material 110 may be formed by injection molding, by an additive process, or by other methods. The encapsulation material 110 extends to the carrier 101 adjacent to the die 103 and adjacent to the intermediate pads 107.

A device identification mark 112 may be formed on the encapsulation material 110 by a raised symbolization feature 113 on the press mold 111. Alternatively, the device identification mark 112 may be formed at a subsequent step of the formation process.

Referring to FIG. 1F, the carrier 101 is removed from the microelectronic device 100 by separating the carrier 101 from the encapsulation material 110 and from the wire bond studs 106. Removal of the carrier 101 may be facilitated using ultrasonic vibrations applied by an ultrasonic transducer 114, as indicated in FIG. 1F. Other methods for removing the carrier 101, such as using a thermal shock, using penetrating solvents, or mechanical cleaving, are within the scope of this example. Removal of the carrier 101 exposes the wire bond studs 106 of the intermediate pads 107.

Referring to FIG. 1G, a plating process using at least one plating bath 115 forms one or more plated metal layers of the intermediate pads 107 on the wire bond studs 106 where exposed by the encapsulation material 110. The one or more plated metal layers may include a base layer 116 on the wire bond studs 106, and a barrier layer 117 on the base layer 116. The chemistry of the plating bath 115 may be changed to provide desired compositions of the one or more plated metal layers. The plating process may be implemented as an autocatalytic electroless process or an immersion process, for example. An autocatalytic electroless process may be continued as long as needed to provide a desired thickness of the metal layer. An immersion process is substantially self-limiting, producing a metal layer that is a few nanometers thick. The base layer 116 may include a metal with a high electrical conductivity, such as copper, and may be formed to be 50 microns to 150 microns thick, to interconnect the wire bond studs 106 in each intermediate pad 107 through low resistance connections. The barrier layer 117 may include one or more metals that reduce diffusion between metal in the base layer 116 and subsequently formed leads, shown in FIG. 1K, on the intermediate pads 107. The barrier layer 117 may include, for example, nickel, palladium, cobalt, titanium, or molybdenum. The barrier layer 117 may be formed to be 5 microns to 20 microns thick, for example. The base layer 116 and the barrier layer 117 may be characterized by a conformal configuration on the wire bond studs 106, in which the base layer 116 and the barrier layer 117 conform to contours of the wire bond studs 106, resulting from the plating process. The base layer 116 and the barrier layer 117 are parts of the intermediate pads 107, along with the wire bond studs 106, in this example. Forming the base layer 116 and the barrier layer 117 without using a photolithographic process, and thus forming the intermediate pads 107 without using a photolithographic process, may further reduce the fabrication cost and the fabrication complexity of the microelectronic device 100.

Referring to FIG. 1H, the microelectronic device 100 is singulated from the additional microelectronic devices 100a by cutting through the encapsulation material 110 in singulation lanes 118 between the microelectronic device 100 and the additional microelectronic devices 100a. The microelectronic device 100 may be singulated by a saw process using a saw blade 119, as indicated in FIG. 1H. Singulating the microelectronic device 100 may be facilitated by the absence of metal in the singulation lanes 118. Other methods of singulating the microelectronic device 100, such as using a laser ablation process or using a water jet process, are within the scope of this example.

FIG. 1I depicts a lead frame 120 with package leads 121 which extend into an area for the microelectronic device 100 of FIG. 1H and areas for the additional microelectronic devices 100a of FIG. 1H. The package leads 121 are not constrained by requirements for wire bonding, such as tight spacing or wirebondable surfaces, and so may have relaxed dimensions and less expensive surface materials compared to leads used for wirebonding. The lead frame 120 may include, for example, stainless steel, or copper clad with stainless steel, to provide a desired balance between mechanical strength and electrical resistance. The package leads 121 do not require surface features to provide adhesion to mold compounds, such as roughened surface areas or etched contours, commonly used to promote adhesion to mold compounds. Thus, the lead frame 120 may be formed by stamping, which may reduce a fabrication cost for the lead frame 120, and thus may reduce a fabrication cost for the microelectronic device 100. Other materials for the lead frame 120 and methods of forming the lead frame 120 are within the scope of this example.

Referring to FIG. 1J, the package leads 121 are attached to the intermediate pads 107, while the package leads 121 are attached to the lead frame 120 of FIG. 1I. The package leads 121 may be attached to the intermediate pads 107 by a welding process using a welding apparatus 122, depicted in FIG. 1J as welding tips 122. The barrier layer 117 of the intermediate pads 107 may advantageously reduce diffusion of copper in the base layer 116 of the intermediate pads 107 into the weld zone between the intermediate pads 107 and the package leads 121, thus providing improved reliability for the microelectronic device 100. Other methods for attaching the package leads 121 to the intermediate pads 107, such as laser welding, or soldering, are within the scope of this example.

Referring to FIG. 1K, the package leads 121 are severed from the lead frame 120 of FIG. 1I. The package leads 121 may be severed from the lead frame 120 by a shearing process, by a laser ablation process, or by another method.

Referring to FIG. 1L, the package leads 121 are shaped to provide a desired package format for the microelectronic device 100. The package leads 121 may be shaped by press forming, by clamping and bending, or by another method. In one version of this example, the package leads 121 may be shaped so as to provide a leadless package format for the microelectronic device 100, as depicted in FIG. 1L. In another version, the package leads 121 may be shaped so as to provide a leaded package format.

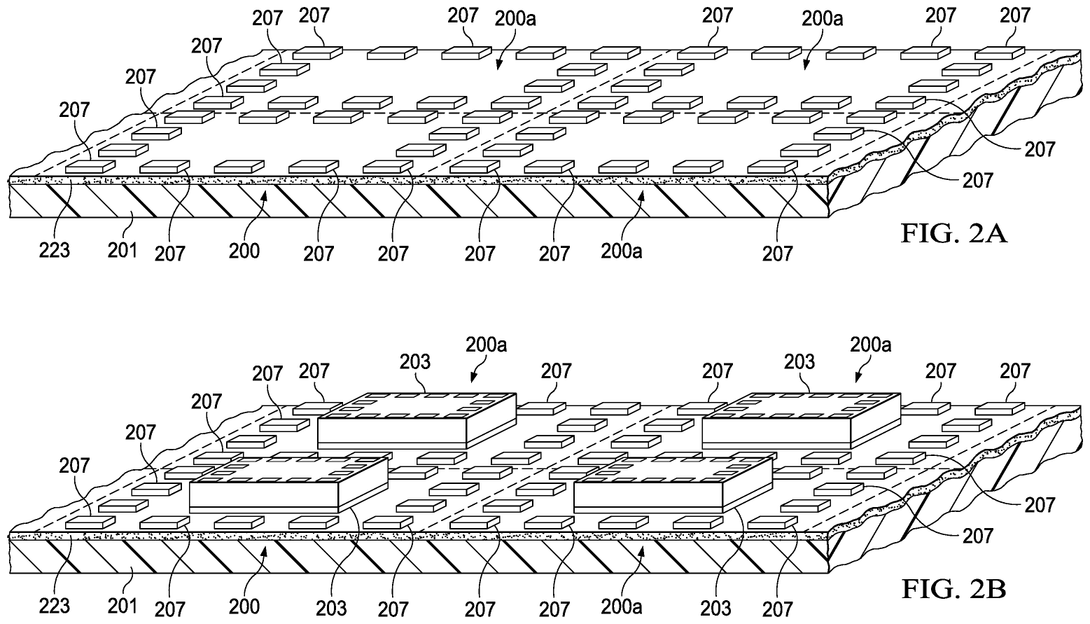

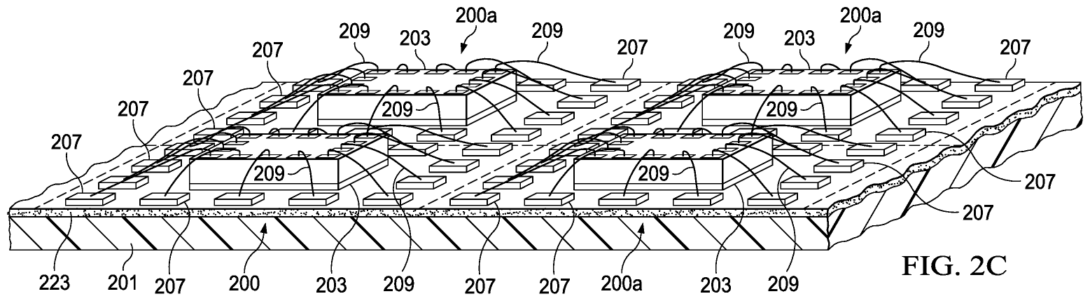

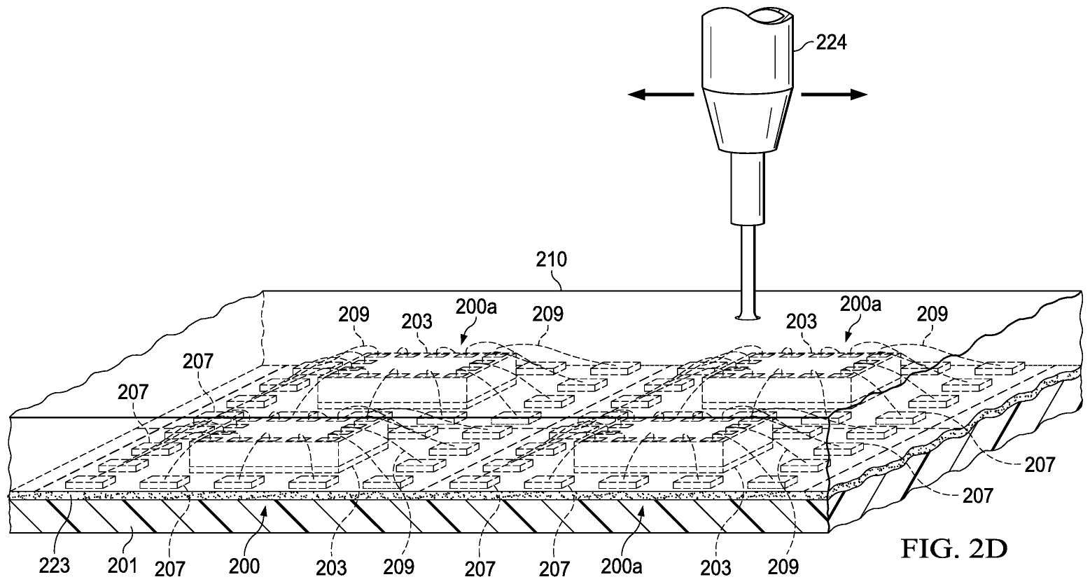

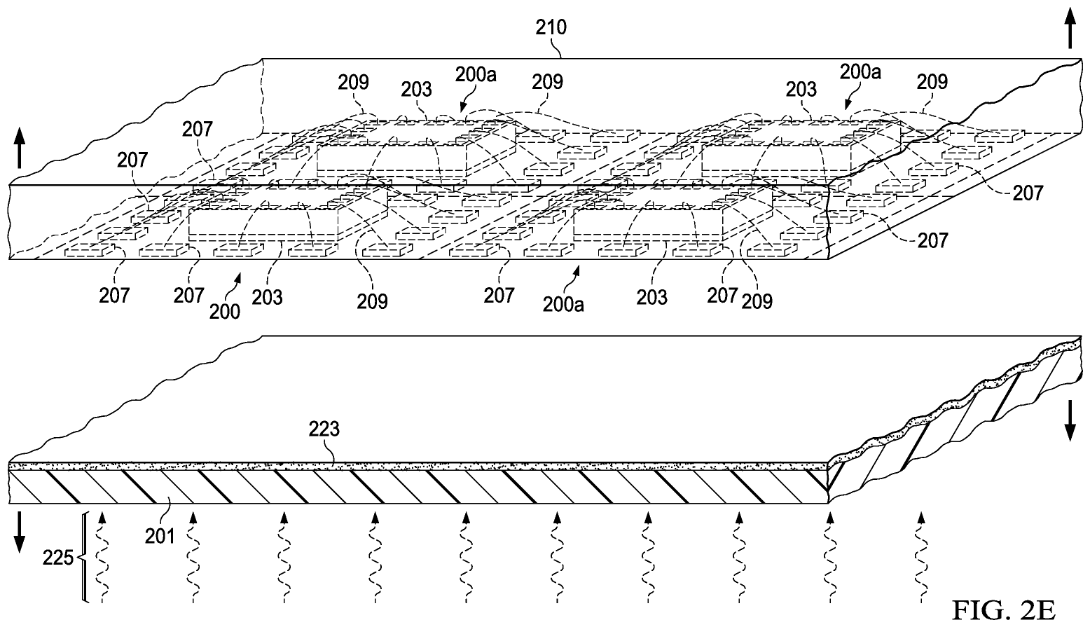

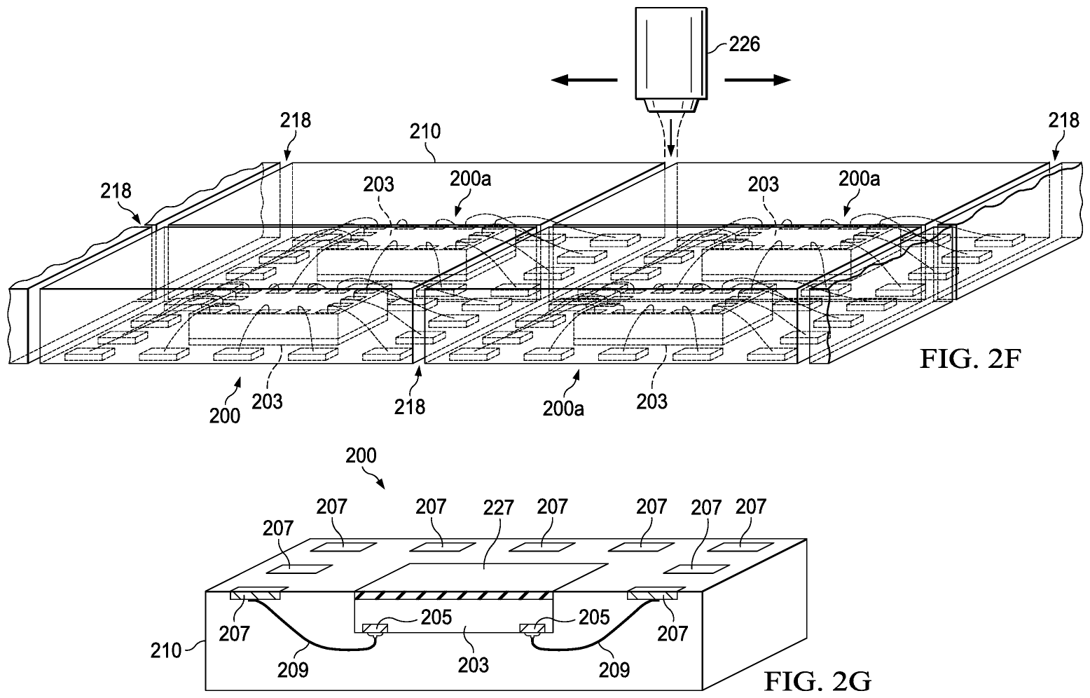

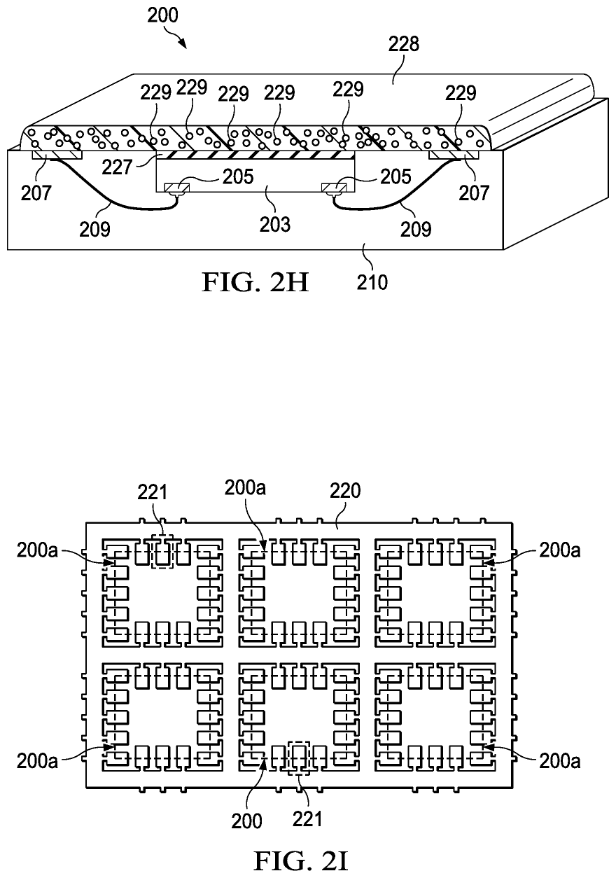

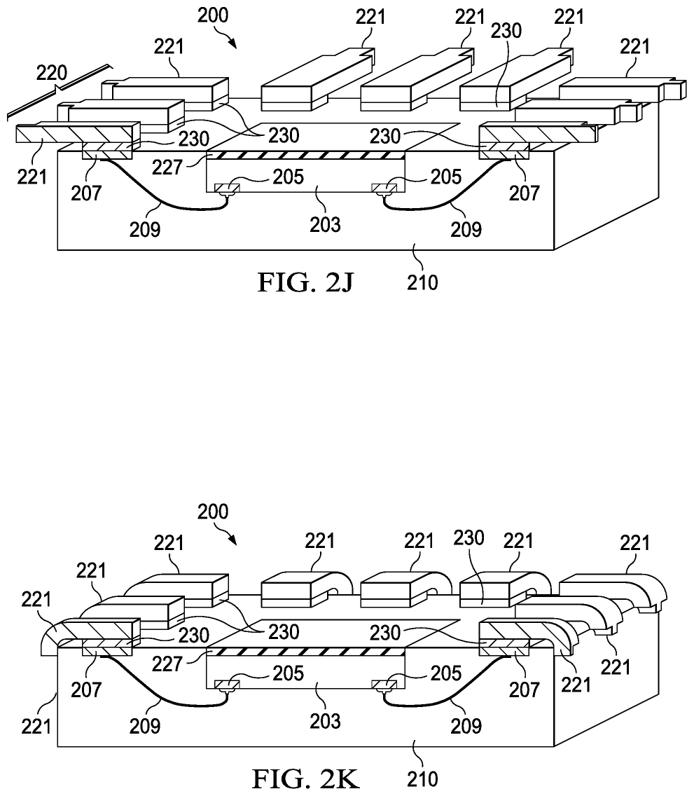

FIG. 2A through FIG. 2K include perspectives and cross sections of a microelectronic device having a leaded/leadless chip scale package, depicted in stages of another example method of formation. Referring to FIG. 2A, formation of the microelectronic device 200 begins by providing a carrier 201. The carrier 201 includes one or more materials suitable as a substrate for forming wire bond studs. In this example, the carrier 201 may be rigid, to facilitate formation of the wire bond studs. The carrier 201 may include, for example, glass, sapphire, silicon, metal, or ceramic. The carrier 201 may have a laminated structure, with a thin, hard surface layer, attached to a mechanically durable substrate. Other compositions and structures for the carrier 201 are within the scope of this example. The carrier 201 may have alignment marks, not shown in FIG. 2A, to assist subsequent placement of die on the carrier 201.

A releasable adhesive 223 is disposed on the carrier 201. The releasable adhesive 223 may include, for example, a thermolabile material, sometimes referred to as thermal release material, which reduces adhesion of the releasable adhesive 223 upon being heated to a prescribed temperature. Commercially available adhesives with thermolabile materials have a range of prescribed temperatures, from 75° C. to 200° C. Other manifestations of the releasable adhesive 223, such as an ultraviolet (UV) release material, which reduces adhesion of the releasable adhesive 223 upon exposure to UV light, are within the scope of this example.

Intermediate pads 207 are disposed on the releasable adhesive 223 in areas for the microelectronic device 200 and in separate areas for additional microelectronic devices 200a. The intermediate pads 207 of the instant example may be implemented as preformed metal pads. The intermediate pads 207 may be individually placed on the releasable adhesive 223, or may be applied in a preconfigured pattern using a tape backing. The intermediate pads 207 of the instant example are disposed on the releasable adhesive 223 without using a photolithographic process, which may advantageously reduce a fabrication cost and a fabrication complexity of the microelectronic device 200. The intermediate pads 207 may include layers to facilitate wire bonding, provide low resistance, and reduce formation of intermetallic compounds. For example, the intermediate pads 207 may include a barrier layer on the releasable adhesive 223 to reduce diffusion of copper in the intermediate pads 207 and tin in a subsequently-formed solder joint, so as to mitigate formation of copper-tin intermetallic compounds. Formation of copper-tin intermetallic compounds is linked to reduced reliability. The intermediate pads 207 may further include a base layer of copper or a copper alloy, over the barrier layer, to provide a desired low resistance in the intermediate pads 207. The base layer may be, for example, 50 microns to 250 microns thick. Copper or a copper alloy is advantageous for the base layer, due to a combination of low cost and low resistance, compared to gold, nickel, or silver. The intermediate pads 207 may also include a wire bondable layer over the base layer, to provide an oxidation-resistant surface for wire bonding. The wire bondable layer may include, for example, gold or platinum, and may be 100 nanometers to 2 microns thick. The intermediate pads 207 may include an adhesion layer of titanium or a titanium alloy between the base layer and the wire bondable layer, to provide adhesion of the wire bondable layer to the base layer and reduce diffusion of copper from the base layer into the wire bondable layer.

Referring to FIG. 2B, multiple die 203 are attached to the releasable adhesive 223. One of the die 203 is attached to the carrier 201 in an area for the microelectronic device 200, and additional die 203 are attached to the carrier 201 in separate areas for additional microelectronic devices 200a. The die 203 may be manifested as integrated circuits, discrete semiconductor components, electro-optical devices, MEMS devices, or other microelectronic die. The die 203 may all be substantially similar devices, or may include more than one device type. The die 203 are positioned adjacent to the intermediate pads 207 for the corresponding microelectronic devices 200 and 200a.

Referring to FIG. 2C, wire bonds 209 are formed by a wire bonding process to connect the die 203 to the intermediate pads 207. FIG. 2C depicts the wire bonds 209 as formed using round bond wire. Other types of bond wire, such as ribbon bond wire, are within the scope of this example. The wire bonds 209 may include, for example, copper wire, coated copper wire, gold wire, or aluminum wire. The wire bonds 209 may be formed with ball bonds on the die 203 and stitch bonds on the intermediate pads 207, or may be formed with ball bonds on the intermediate pads 207 and stitch bonds on the die 203. The die 203 may have terminals 205, shown in more detail in FIG. 2G, for electrical connections to components in the die 203. The wire bonds 209 may terminate on the terminals 205.

Referring to FIG. 2D, an encapsulation material 210 is formed over the die 203, the wire bonds 209, and the intermediate pads 207. The encapsulation material 210 contacts the intermediate pads 207. The encapsulation material 210 may include epoxy or other material suitable for protecting the die 203 and the wire bonds 209 from moisture and contamination. The encapsulation material 210 may be formed by an additive process using a material extrusion apparatus 224. Alternatively, the encapsulation material 210 may be formed by injection molding, by press molding, or by other methods. The encapsulation material 210 extends to the carrier 201 adjacent to the die 203 and adjacent to the intermediate pads 207.

Referring to FIG. 2E, the carrier 201 and the releasable adhesive 223 are removed from the microelectronic device 200 by separating the releasable adhesive 223 from the encapsulation material 210 and from the intermediate pads 207. In the case of the releasable adhesive 223 being implemented with a thermolabile material, removal of the carrier 201 and the releasable adhesive 223 may be performed in this example by heating the releasable adhesive 223 by a heating process 225 to a prescribed temperature, for example, a temperature in a range of 75° C. to 200° C., as indicated in FIG. 2E. The heating process 225 may be implemented as a radiative heating process, as indicated in FIG. 2E, or may be implemented as a hot plate process, a forced air convection heating process, or an oven bake process. In the case of the releasable adhesive 223 being implemented with a photolabile material, the carrier 201 and the releasable adhesive 223 may be removed by exposure to UV light through the carrier 201. In the case of the releasable adhesive 223 being implemented with other materials, other methods for removing the carrier 201 and the releasable adhesive 223, may be used as appropriate. Removal of the releasable adhesive 223 exposes the intermediate pads 207.

Referring to FIG. 2F, the microelectronic device 200 is singulated from the additional microelectronic devices 200a by cutting through the encapsulation material 210 in singulation lanes 218 between the microelectronic device 200 and the additional microelectronic devices 200a. The microelectronic device 200 may be singulated by a laser ablation process using a laser 226, as indicated in FIG. 2F. Singulating the microelectronic device 200 may be facilitated by the absence of metal in the singulation lanes 218.

FIG. 2G depicts the microelectronic device 200 after singulating from the additional microelectronic devices 200a of FIG. 2F. The microelectronic device 200 is depicted in FIG. 2G in an inverted orientation with respect to FIG. 2F. The die 203 may have terminals 205 on which the wire bonds 209 are terminated. The terminals 205 may be manifested as bond pads, or circuit nodes. The terminals 205 may include materials suitable for wire bonding.

The die 203 may have an electrically insulating layer 227 to isolate electrical conductors and semiconductor material in the die 203 from exposure to an exterior of the microelectronic device 200. The electrically insulating layer 227 may include, for example, silicon dioxide, silicon nitride, or polyimide.

Referring to FIG. 2H, in this example, a solder anisotropic conductive film 228 is applied to the microelectronic device 200, contacting the intermediate pads 207. The solder anisotropic conductive film 228 may include solder particles 229 in an adhesive binder. The solder anisotropic conductive film 228 may be applied in a tape format, or may be applied in a paste format. The solder anisotropic conductive film 228 is commercially available from various suppliers.

FIG. 2I depicts a lead frame 220 with package leads 221 which extend into an area for the microelectronic device 200 and areas for the additional microelectronic devices 200a. The package leads 221 of this example are not constrained by requirements for wire bonding, and do not require surface features to provide adhesion to mold compounds, similar to the package leads 121 of FIG. 1I, thus accruing similar advantages to the advantages disclosed in reference to the microelectronic device 100 of FIG. 1J. The lead frame 220 may have a similar composition and structure to the lead frame 120 of FIG. 1I, and may be formed by a process, such as stamping, similar to a process used to form the lead frame 120.

Referring to FIG. 2J, the lead frame 220 is positioned on the microelectronic device 200, contacting the solder anisotropic conductive film 228 of FIG. 2H. The lead frame 220 is positioned so that the package leads 221 align with the intermediate pads 207. The solder anisotropic conductive film 228 is heated, causing the solder particles 229 of FIG. 2H to melt and collect in solder connections 230 that connect the intermediate pads 207 with the package leads 221. Remaining material of the solder anisotropic conductive film 228, including the adhesive binder, is not shown in FIG. 2J to more clearly show the solder connections 230.

Referring to FIG. 2K, the package leads 221 are severed from the lead frame 220 of FIG. 2J. The package leads 221 may be severed from the lead frame 220 as disclosed in reference to the lead frame 120 of FIG. 1K. The package leads 221 are shaped to provide a desired package format for the microelectronic device 200. The package leads 221 may be shaped as disclosed in reference to the package leads 121 of FIG. 1K. The package leads 221 may be shaped so as to provide a leadless package format for the microelectronic device 200, as depicted in FIG. 2K, or may be shaped so as to provide a leaded package format.

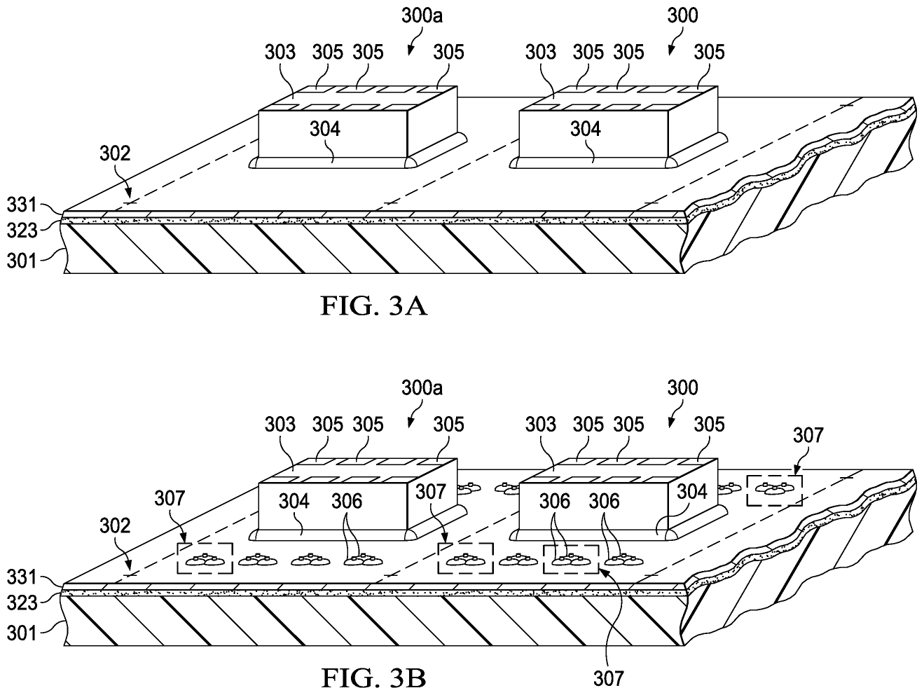

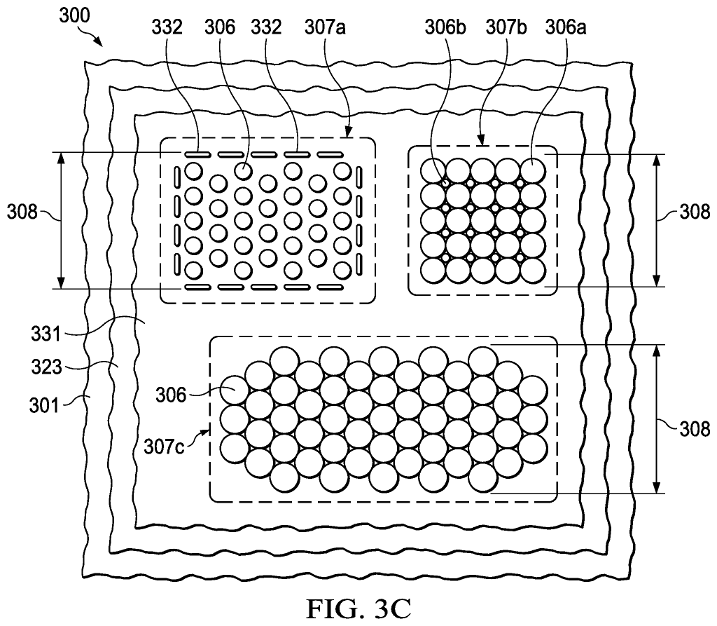

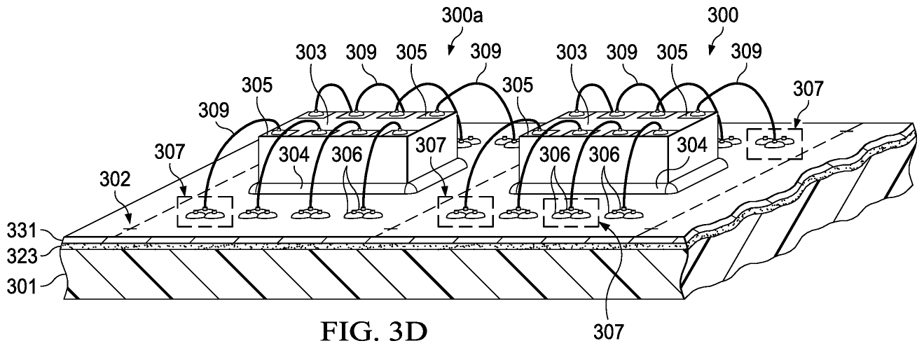

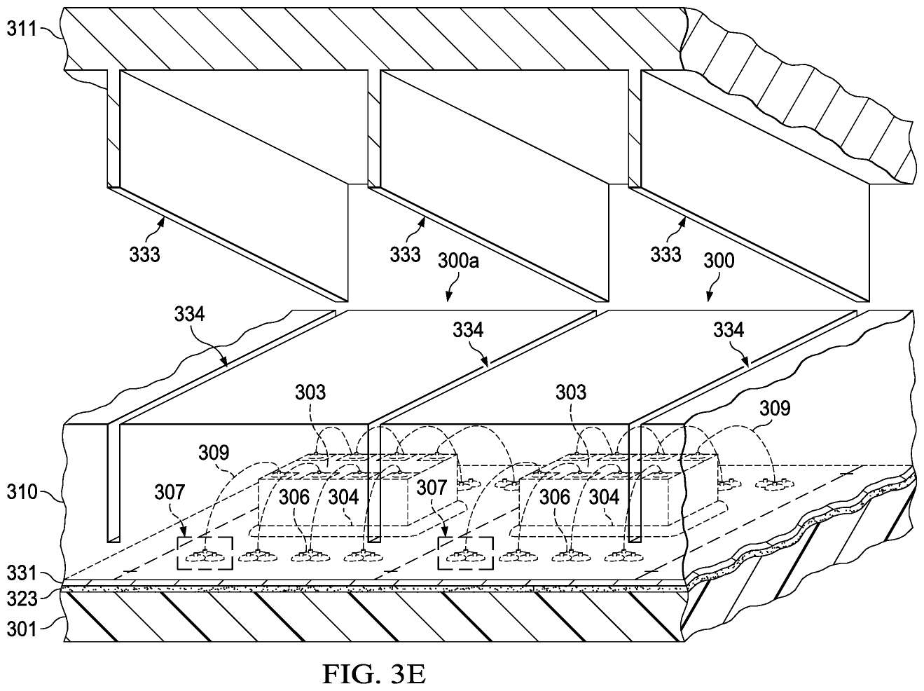

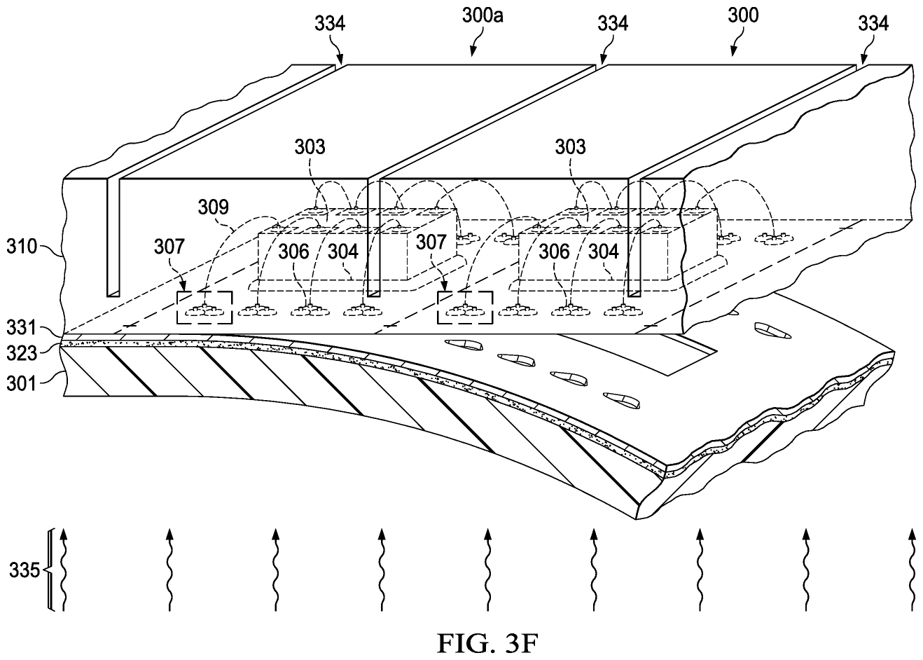

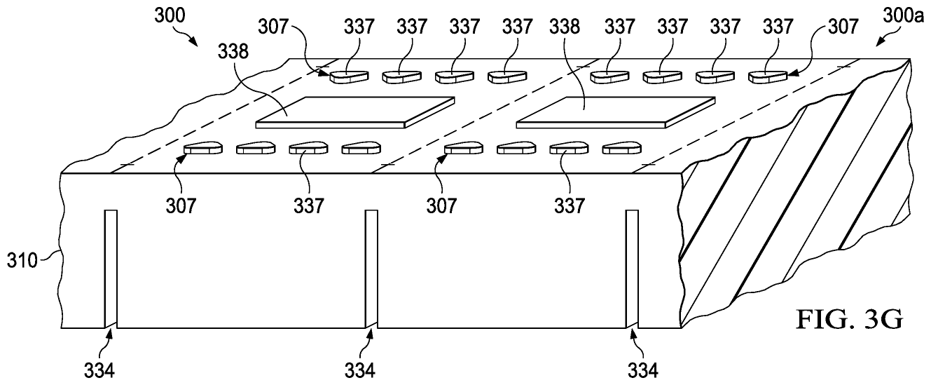

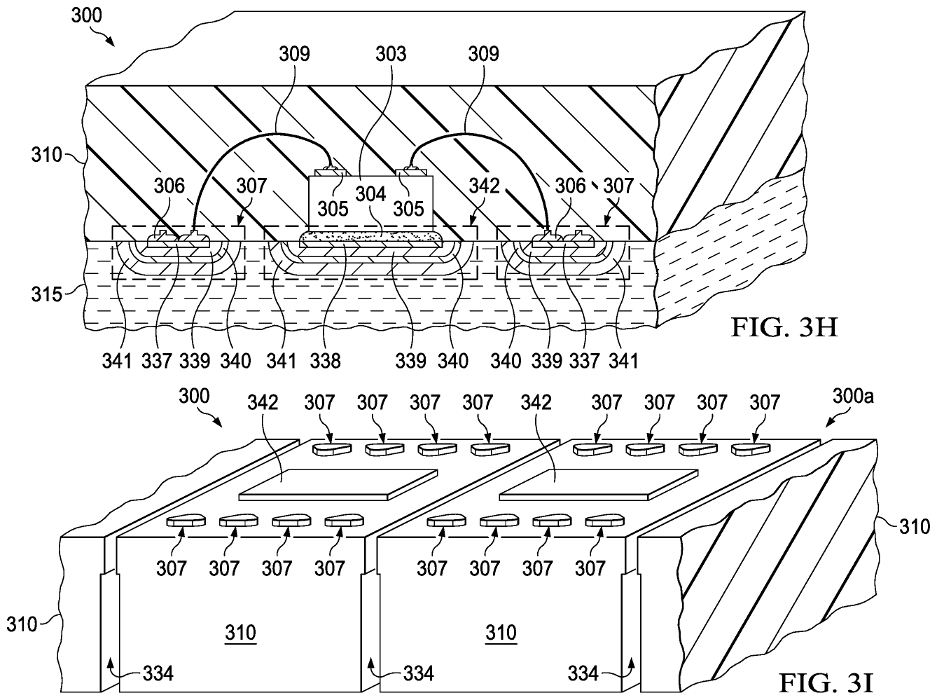

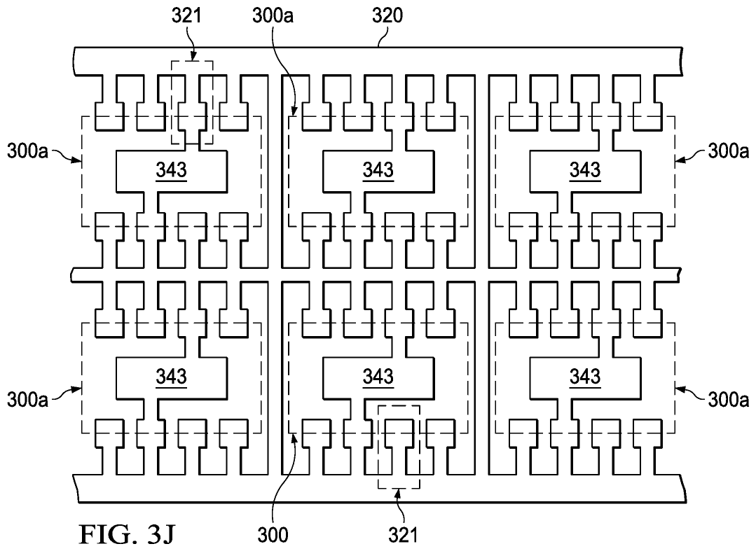

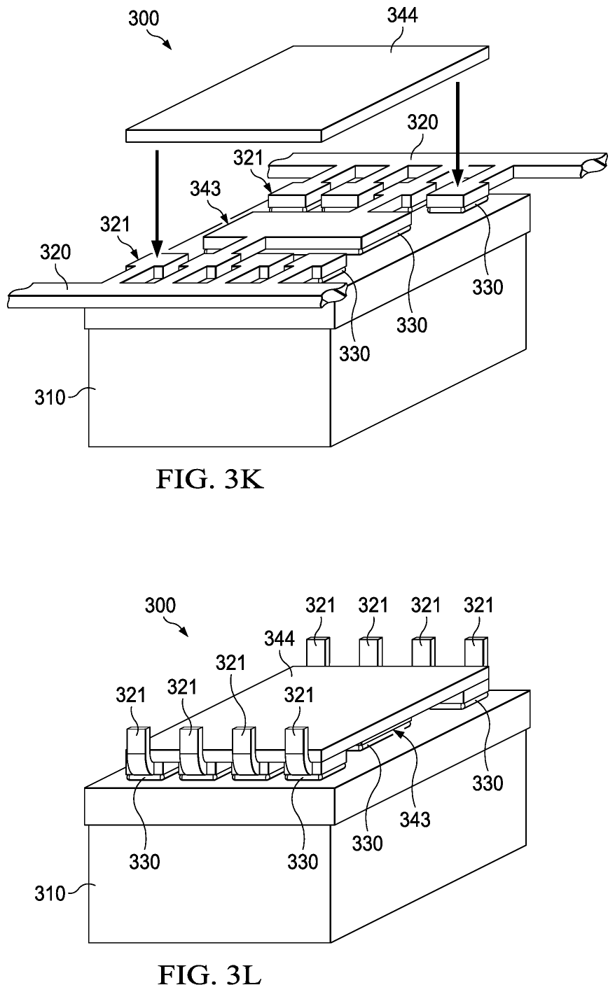

FIG. 3A through FIG. 3L include perspectives and cross sections of a microelectronic device having a leaded/leadless chip scale package, depicted in stages of a further example method of formation. Referring to FIG. 3A, formation of the microelectronic device 300 begins by providing a carrier 301. The carrier 301 includes one or more materials suitable as a substrate for forming wire bond studs. In this example, the carrier 301 may be flexible, to facilitate subsequent removal from the microelectronic device 300. The carrier 301 may include, for example, polycarbonate, high density polyethylene, polydimethylsiloxane (PDMS), or polyurethane. The carrier 301 may be reinforced with fibers, such as glass fibers, to provide mechanical integrity. Other compositions and structures for the carrier 301 are within the scope of this example. The carrier 301 may have alignment marks 302 to assist subsequent placement of die on the carrier 301.

A releasable adhesive 323 is disposed on the carrier 301. The releasable adhesive 323 may include, for example, a photolabile material, which exhibits reduced adhesion after exposure to light in a prescribed wavelength band, for example, a UV band. In versions of this example in which the releasable adhesive 323 is implemented with a photolabile material, the carrier 301 is transmissive to light in the prescribed wavelength band. Other manifestations of the releasable adhesive 323, such as a thermolabile material, are within the scope of this example.

A pad metal layer 331 is disposed on the releasable adhesive 323. The pad metal layer 331 includes metal suitable for forming wire bond studs or ribbon bond wire stitch strips. The pad metal layer 331 also includes metal suitable for forming a seed layer for a subsequent plating process. The pad metal layer 331 may have several sublayers of metal, for example a protective layer of nickel, gold, platinum, or palladium that contacts the releasable adhesive 323, a base layer of copper or copper alloy on the protective layer, and a wire bondable layer of gold or platinum on the base layer. The base layer may be for example, 50 microns to 250 microns thick. In one version of this example, the pad metal layer 331 may be continuous, with no detachment lines to define areas for intermediate pads. In another version, the pad metal layer 331 may have perforations, indents, creases, crimped lines, thinned lines, or such, to define areas for intermediate pads and to assist separation of the pad metal layer 331 in the areas for the intermediate pads from the remaining pad metal layer 331.

Multiple die 303 are attached to the pad metal layer 331, in this example. One of the die 303 is attached to the pad metal layer 331 in an area for the microelectronic device 300, and additional die 303 are attached to the pad metal layer 331 in separate areas for additional microelectronic devices 300a. The die 303 may be manifested as integrated circuits, discrete semiconductor components, electro-optical devices, MEMS devices, or other microelectronic die. The die 303 may all be substantially similar devices, for example, may all be instances of a particular power transistor. Alternatively, the die 303 may include more than one device type.

The die 303 may have terminals 305 for electrical connections to components in the die 303. The terminals 305 may be manifested as bond pads, or may be manifested as circuit nodes, such as transistor source and drain nodes. The terminals 305 may include materials suitable for wire bonding, such as aluminum, copper, gold, or platinum.

The die 303 may be attached to the pad metal layer 331 by a die attach material 304, such as an electrically conductive adhesive or solder. The die attach material 304 of this example is electrically conductive, to electrically connect a substrate of the die 303 to the pad metal layer 331.

Referring to FIG. 3B, wire bond studs 306 are formed on the pad metal layer 331 adjacent to the die 303, using a wire bonding process. The wire bond studs 306 may be formed by pressing a free air ball of a bond wire onto the pad metal layer 331 with a wire bonding capillary to form a stud, and subsequently severing the bond wire proximate to the stud. The wire bond studs 306 may include primarily copper or gold, and may have some nickel or palladium from a barrier layer around the bond wire. The wire bond studs 306 and portions of the pad metal layer 331 immediately below the wire bond studs 306 form initial portions of intermediate pads 307.

FIG. 3C depicts example configurations of the wire bond studs 306 in the intermediate pads 307 of FIG. 3B. A first intermediate pad 307a may be implemented as a hexagonal array, with wire bond studs 306 of substantially equal sizes, as a result of being formed with equal diameter bond wire and equal force on the wire bonding capillary. Adjacent wire bond studs 306 may be separated from each other in the first intermediate pad 307a, by a space that is sufficiently small that the pad metal layer 331 will remain connected to, and continuous between, the adjacent wire bond studs 306 when the carrier 301 is removed from the microelectronic device 300. For example, the adjacent wire bond studs 306 may be separated by a space that is 1 to 5 times a thickness of the pad metal layer 331. The first intermediate pad 307a may have a minimum lateral dimension 308 of 150 microns to 300 microns. The term “lateral” refers to a direction parallel to a face of the pad metal layer 331 on which the wire bond studs 306 are formed. The minimum lateral dimension 308 may be selected to maintain current density through the first intermediate pad 307a, during operation of the microelectronic device 300, below a target value, to provide a desired level of reliability.

The first intermediate pad 307a includes a contiguous portion of the pad metal layer 331 contacting the wire bond studs 306. The pad metal layer 331 may include pad separation features 332 which surround the first intermediate pad 307a, to facilitate separation of the contiguous portion of the pad metal layer 331 of the first intermediate pad 307a from a remainder of the pad metal layer 331, when the carrier 301 is removed from the microelectronic device 300. The pad separation features 332 may be implemented as perforations through the pad metal layer 331, indentations in the pad metal layer 331, or other such structures that facilitate separation of the pad metal layer 331 around the first intermediate pad 307a.

A second intermediate pad 307b may have a square array configuration, with first wire bond studs 306a of substantially equal first sizes, and second wire bond studs 306b of substantially equal second sizes, smaller than the first size. The second wire bond studs 306b may be disposed between the first wire bond studs 306a to provide a higher fill factor of electrically conductive material in the second intermediate pad 307b. Adjacent first wire bond studs 306a and second wire bond studs 306b contact each other in the second intermediate pad 307b, to form a contiguous electrically conductive array on the pad metal layer 331. The second intermediate pad 307b may have a minimum lateral dimension 308 of 150 microns to 300 microns, to provide desired level of reliability as explained in reference to the first intermediate pad 307a.

A third intermediate pad 307c may have an elongated configuration, with wire bond studs 306 of substantially equal sizes arranged in a hexagonal array. Adjacent wire bond studs 306 may contact each other, to provide a lower resistance in the third intermediate pad 307c. The third intermediate pad 307c may have a minimum lateral dimension 308 of 150 microns to 300 microns, and may have a length significantly longer than the minimum lateral dimension 308, to provide desired level of reliability as explained in reference to the first intermediate pad 307a. The elongated configuration of the third intermediate pad 307c may be appropriate for power and ground connections to the microelectronic device 300 of FIG. 1B, which commonly conduct significantly more current than signal connections.

The pad separation features 332 may be implemented in versions of the second intermediate pad 307b or the third intermediate pad 307c. Intra-pad wire bonds, disclosed in the commonly assigned U.S. patent application Ser. No. 12/______, Attorney Docket Number TI-78741, filed concurrently with this application, may be implemented in versions of the first intermediate pad 307a, the second intermediate pad 307b or the third intermediate pad 307c.

Referring to FIG. 3D, wire bonds 309 are formed by a wire bonding process to connect the die 303 to the intermediate pads 307. FIG. 3D depicts the wire bonds 309 as formed using round bond wire. Other types of bond wire, such as ribbon bond wire, are within the scope of this example. The wire bonds 309 may include, for example, copper wire, coated copper wire, gold wire, or aluminum wire. The wire bonds 309 may be formed with ball bonds on the die 303 and stitch bonds on the intermediate pads 307, or may be formed with ball bonds on the intermediate pads 307 and stitch bonds on the die 303. The wire bonds 309 may terminate on the wire bond studs 306, or may terminate on the pad metal layer 331 among the wire bonds 309 in the intermediate pads 307.

Referring to FIG. 3E, an encapsulation material 310 is formed over the die 303, the wire bonds 309, and the wire bond studs 306. The encapsulation material 310 contacts the intermediate pads 307. The encapsulation material 310 may include epoxy or other material suitable for protecting the die 303 the wire bonds 309, and the wire bond studs 306 from moisture and contamination. In this example, the encapsulation material 310 may be formed by using a press mold 311 having singulation fins 333, which produce singulation trenches 334 in the encapsulation material 310 around a perimeter of the microelectronic device 300. The singulation trenches 334 may facilitate subsequent singulation of the microelectronic device 300 from the additional microelectronic devices 300a. The encapsulation material 310 extends to the pad metal layer 331 adjacent to the die 303 and adjacent to the wire bond studs 306.

Referring to FIG. 3F, the carrier 301 and the releasable adhesive 323 are removed from the microelectronic device 300. Portions of the pad metal layer 331 contacting the wire bond studs 306 remain attached to the wire bond studs 306. A portion of the pad metal layer 331 contacting the die attach material 304 remains attached to the die attach material 304. Removal of the carrier 301 and the releasable adhesive 323 may be performed in this example by exposing the releasable adhesive 323 to UV light 335 through the carrier 301.

FIG. 3G depicts the microelectronic device 300 and the adjacent microelectronic device 300a after removal of the carrier 301 and the releasable adhesive 323 of FIG. 3F. FIG. 3G shows the microelectronic device 300 and the adjacent microelectronic device 300a in an inverted orientation with respect to FIG. 3F. The portions of the pad metal layer 331 of FIG. 3F remaining attached to the wire bond studs 306 of FIG. 3F provide supplementary metal pads 337 of the intermediate pads 307. The portion of the pad metal layer 331 remaining attached to the die attach material 304 of FIG. 3F provides a substrate contact layer 338. The substrate contact layer 338 is electrically connected to the substrate of the die 303 of FIG. 3F through the die attach material 304.

Referring to FIG. 3H, one or more plated metal layers are formed on the supplementary metal pads 337 and on the substrate contact layer 338. The one or more plated metal layers may include a base layer 339 on the supplementary metal pads 337 and on the substrate contact layer 338, a barrier layer 340 on the base layer 339, and a solder layer 341 on the barrier layer 340. The base layer 339 may include copper or copper alloy, and may be formed to have a thickness of 50 microns to 150 microns, to provide a low resistance for the intermediate pads 307. The barrier layer 340 may include one or more metals that reduce diffusion between metal in the base layer 339 and the solder layer 341. The barrier layer 340 may include, for example, nickel, palladium, cobalt, titanium, or molybdenum, and may be formed to have a thickness of 5 microns to 20 microns, for example. The solder layer 341 may include, for example, silver, tin, and copper, and may be formed to have a thickness of 10 microns to 50 microns. The base layer 339, the barrier layer 340, and the solder layer 341 may be formed by a plating process, using a plating bath 315. The chemistry of the plating bath 315 may be changed to provide desired compositions of the base layer 339, the barrier layer 340, and the solder layer 341. The plating process may be implemented as an autocatalytic electroless process or an immersion process, for example. The base layer 339 and the barrier layer 340 may be characterized by a conformal configuration on the supplementary metal pads 337, in which the base layer 339 and the barrier layer 340 conform to contours of the supplementary metal pads 337, resulting from the plating process. As an alternative to plating the solder layer 341, the solder layer 341 may be formed by a solder fountain or a solder bath, or by solder paste. The wire bond studs 306, the supplementary metal pads 337, the base layer 339 on the supplementary metal pads 337, the barrier layer 340, and the solder layer 341 are parts of the intermediate pads 307 in this example. The die attach material 304, the substrate contact layer 338, the base layer 339 on the substrate contact layer 338, the barrier layer 340, and the solder layer 341 are parts of a substrate contact 342 of the microelectronic device 300 in this example.

Referring to FIG. 3I, the microelectronic device 300 is singulated from the additional microelectronic devices 300a by severing through the encapsulation material 310 below the singulation trenches 334 between the microelectronic device 300 and the additional microelectronic devices 300a. The microelectronic device 300 may be singulated by stressing the encapsulation material 310 below the singulation trenches 334 using singulation tape and a breaking dome, for example. Alternatively, the microelectronic device 300 may be singulated by a laser ablation process, a saw process, or a water jet process. Singulating the microelectronic device 300 may be facilitated by the absence of metal in the encapsulation material 310 below the singulation trenches 334.

FIG. 3J depicts a lead frame 320 with package leads 321 which extend into an area for the microelectronic device 300 and areas for the additional microelectronic devices 300a. In this example, the lead frame 320 includes die pads 343 connected to one or more of the package leads 321. The package leads 321 of this example are not constrained by requirements for wire bonding, and do not require surface features to provide adhesion to mold compounds, similar to the package leads 121 of FIG. 1I, thus accruing similar advantages to the advantages disclosed in reference to the microelectronic device 100 of FIG. 1J. The lead frame 320 may have a similar composition and structure to the lead frame 120 of FIG. 1I, and may be formed by a process, such as stamping, similar to a process used to form the lead frame 120.

Referring to FIG. 3K, the lead frame 320 is positioned on the microelectronic device 300, contacting the solder layer 341 of FIG. 3H. The lead frame 320 is positioned so that the package leads 321 align with the intermediate pads 307 of FIG. 3H. The solder layer 341 is heated, causing the solder layer 341 to melt and form solder connections 330 that connect the intermediate pads 307 with the package leads 321, and connects the substrate contact 342 of FIG. 3H with the die pad 343.

A reinforcing layer 344 may optionally be attached to the package leads 321 and the die pad 343, to provide mechanical support to the package leads 321 and the die pad 343. The reinforcing layer 344 may include, for example, ceramic, fiberglass reinforced polymer (FRP), phenolic, or insulated metal. The reinforcing layer 344 may be attached to the package leads 321 and the die pad 343 by an adhesive, tape, or ceramic grout, for example.

Referring to FIG. 3L, the package leads 321 are severed from the lead frame 320 of FIG. 3K. The package leads 321 may be severed from the lead frame 320 as disclosed in reference to the lead frame 120 of FIG. 1K. The package leads 321 are shaped to provide a desired package format for the microelectronic device 300. The package leads 321 may be shaped as disclosed in reference to the package leads 121 of FIG. 1K. The package leads 321 may be shaped so as to provide a leaded package format for the microelectronic device 300, as depicted in FIG. 3K, or may be shaped so as to provide a leadless package format. The reinforcing layer 344 may protect the package leads 321 during subsequent assembly, including mounting the microelectronic device 300 on a circuit substrate.

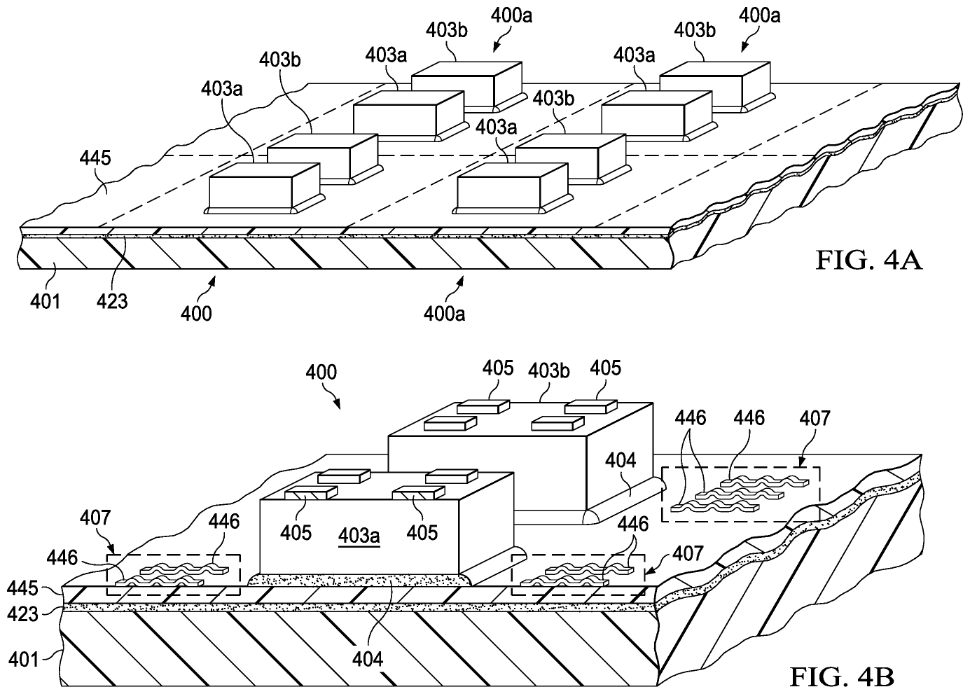

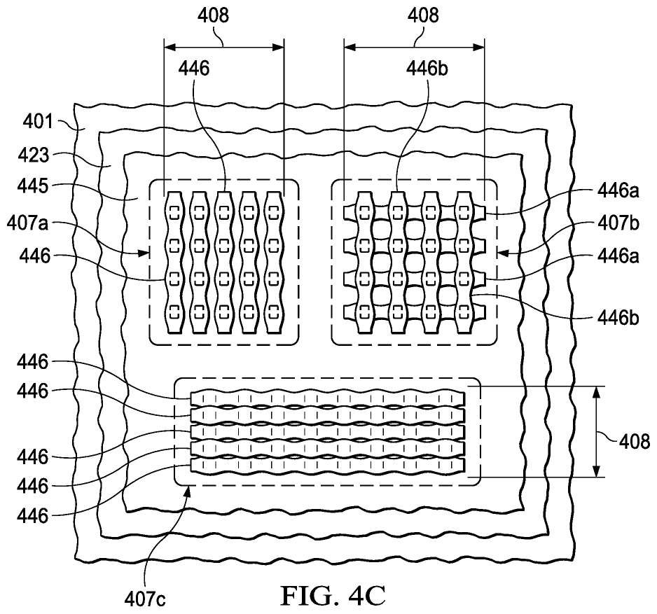

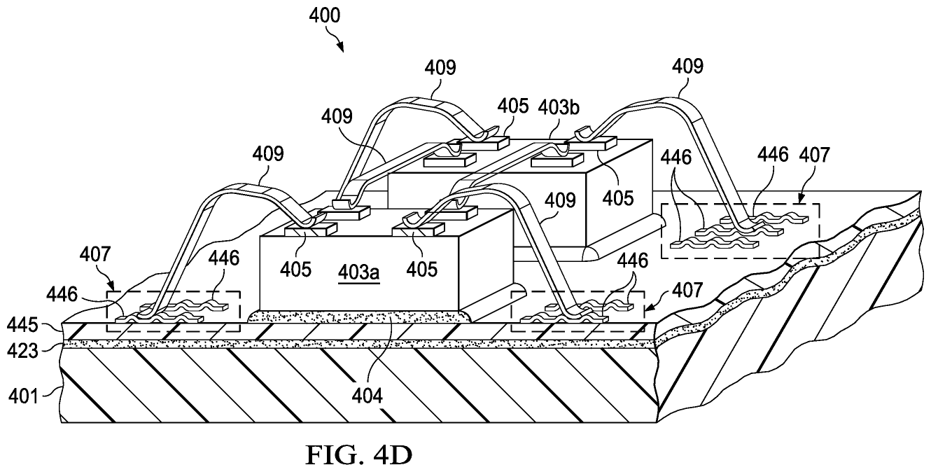

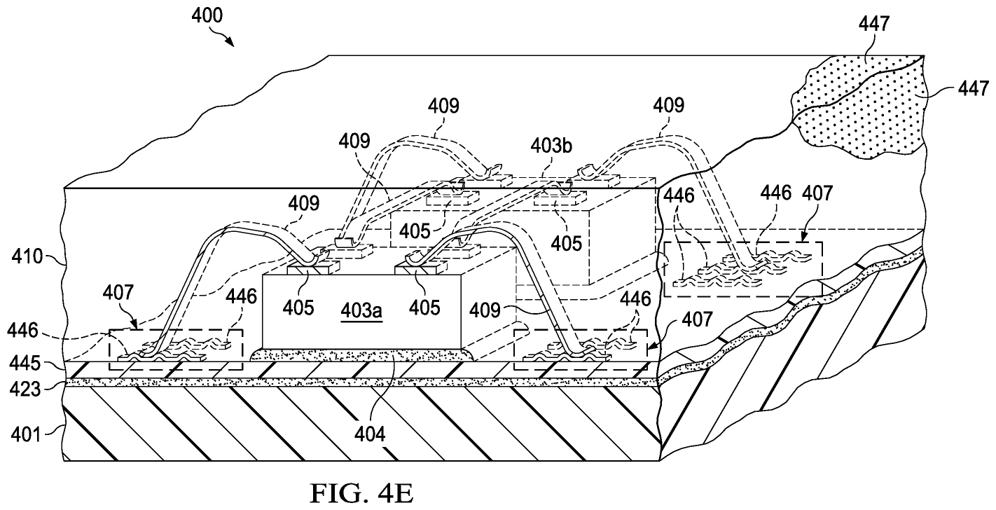

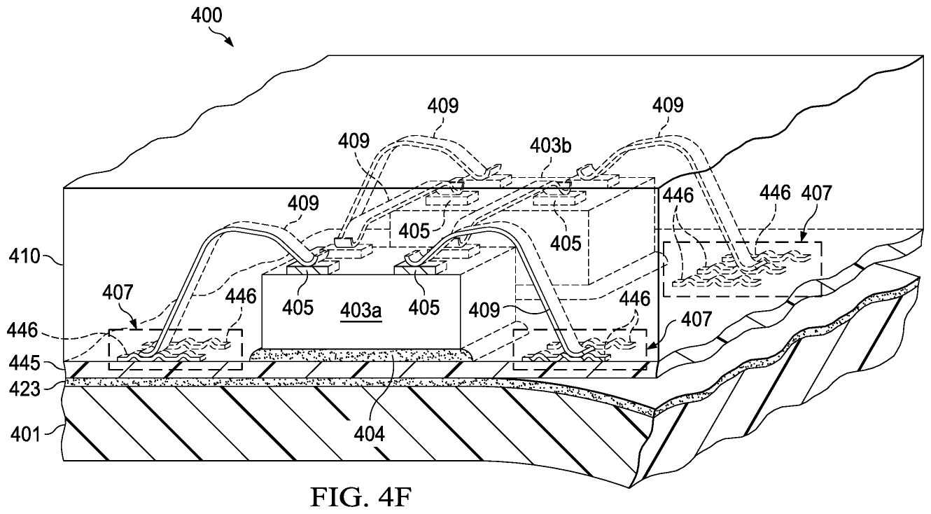

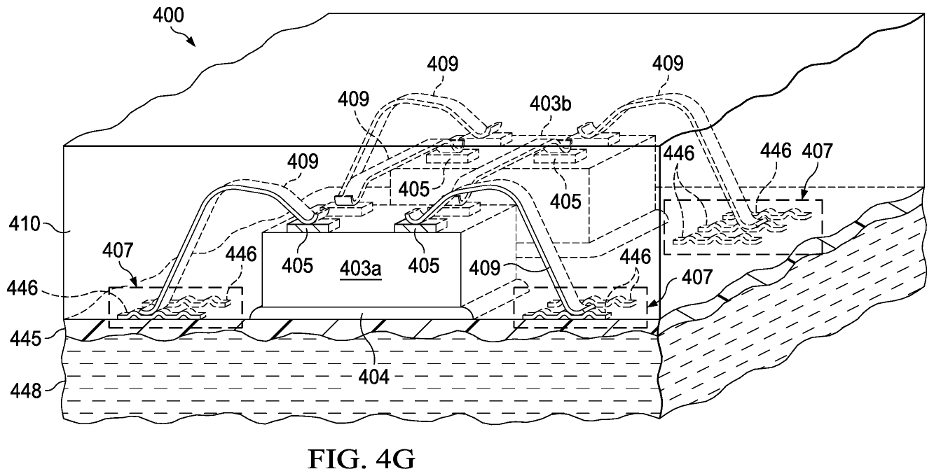

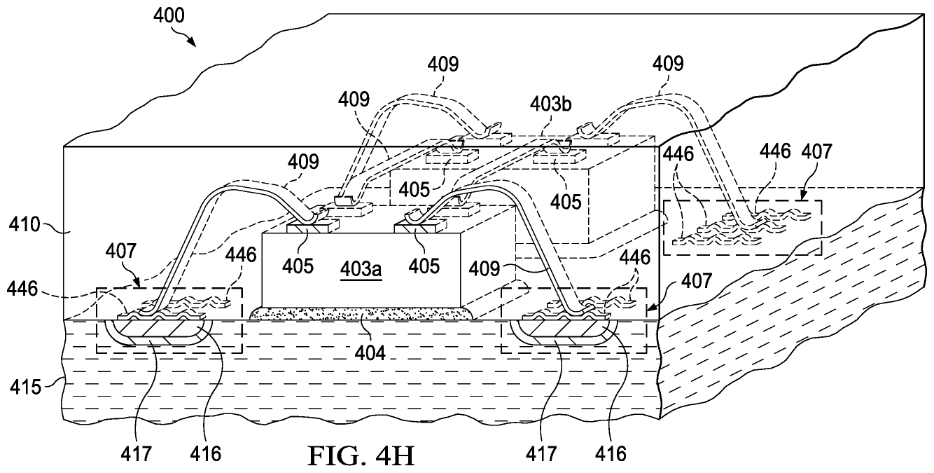

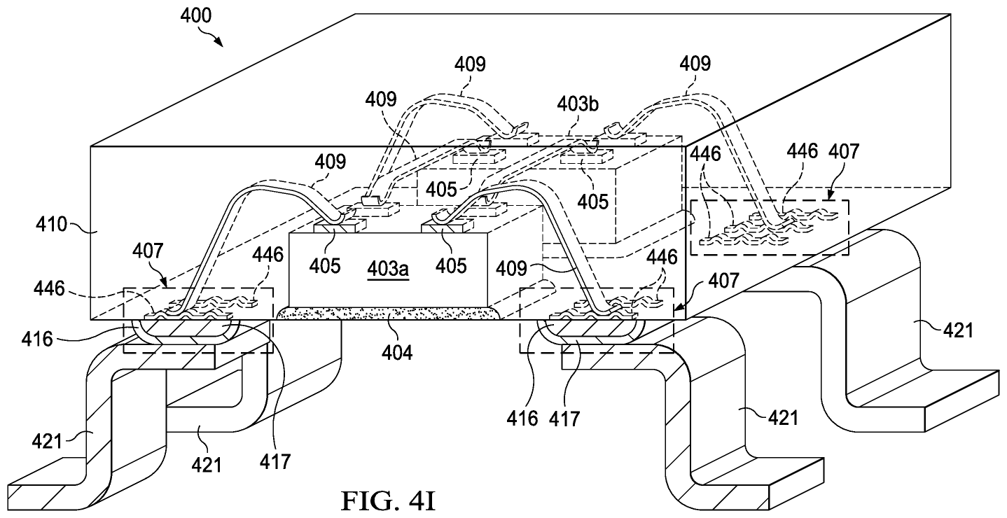

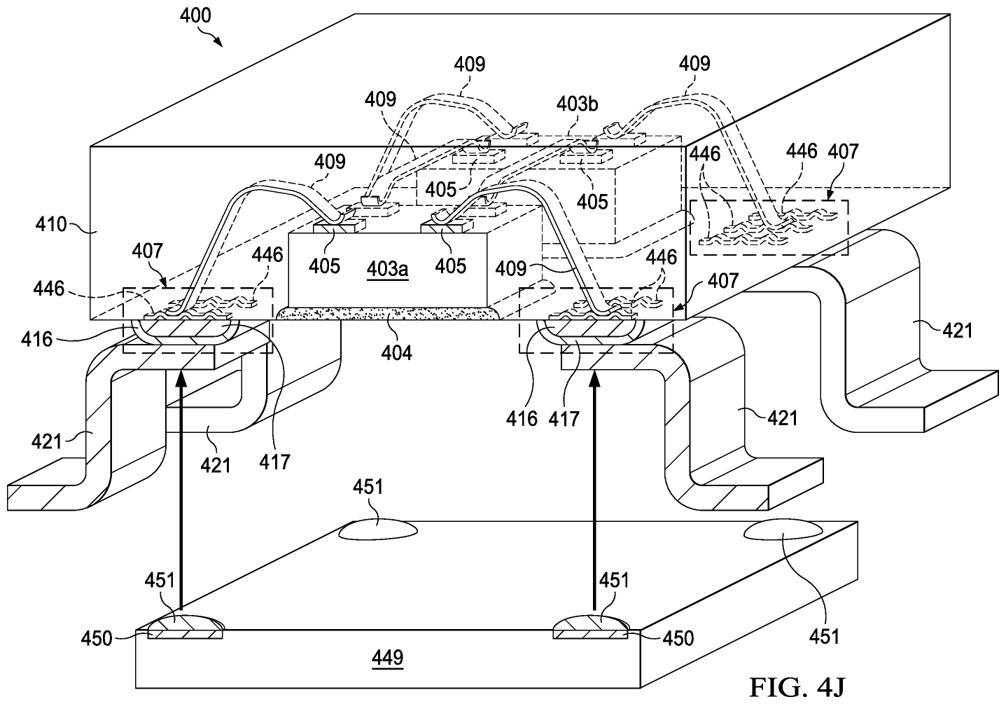

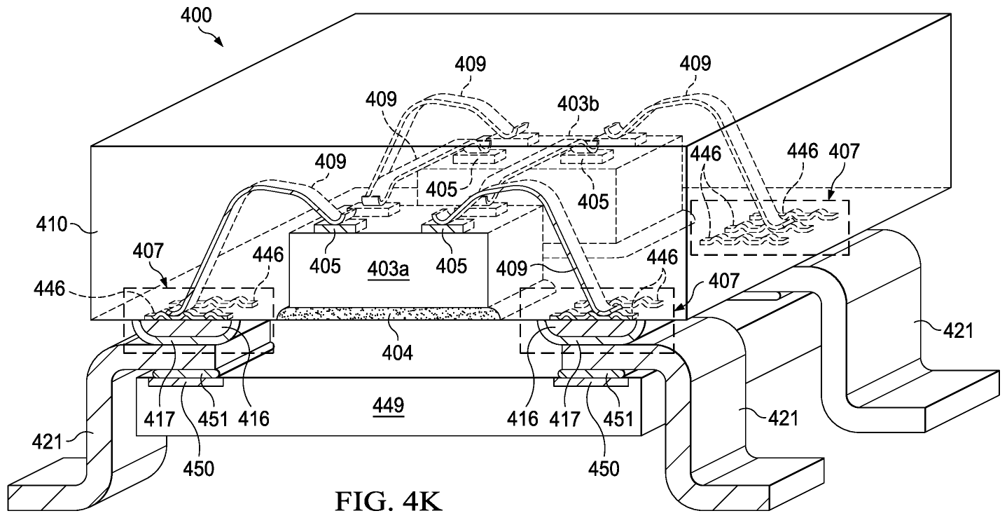

FIG. 4A through FIG. 4K include various views of a microelectronic device having a leaded/leadless chip scale package, depicted in stages of another example method of formation. Referring to FIG. 4A, formation of the microelectronic device 400 begins by providing a carrier 401. In this example, the carrier 401 may be flexible, to facilitate subsequent removal of the carrier 401. The carrier 401 may include, for example, polyethylene, polypropylene, nylon, or polyurethane. The carrier 401 may have a laminated structure, or a fiber-reinforced structure, to provide a desired mechanical strength. Other compositions and structures for the carrier 401 are within the scope of this example. The carrier 401 has an area for the microelectronic device 400, and areas for additional microelectronic devices 400a. The carrier 401 may have alignment marks, not shown in FIG. 4A, to assist subsequent placement of die on the carrier 401.

A releasable adhesive 423 is disposed on the carrier 401. A sacrificial layer 445 is disposed on the releasable adhesive 423. The sacrificial layer 445 includes one or more materials having a hardness suitable for forming ribbon stitch bonds or wire bond studs. The sacrificial layer 445 includes materials which can be removed from the microelectronic device 400 without degrading the microelectronic device 400, for example by a wet etch process. The sacrificial layer 445 may include, for example, aluminum oxide, aluminum nitride, polycrystalline silicon, hydrogen-rich silicon nitride, or phosphosilicate glass (PSG). The sacrificial layer 445 may be 1 micron to 10 microns thick, to facilitate removal from the microelectronic device 400. The releasable adhesive 423 may include, for example, a microsuction tape which has microscopic pores on a face of the releasable adhesive 423 contacting the sacrificial layer 445. The microsuction tape may be permanently affixed to the carrier 401, for example by a permanent adhesive. The microsuction tape may be separated from the sacrificial layer 445 by peeling the carrier 401 from the sacrificial layer 445, advantageously leaving no residue on the sacrificial layer 445. Alternatively, the releasable adhesive 423 may include a silicone layer which exhibits high adhesion to the sacrificial layer 445 in a shear mode, but is easily removed by a peeling process. Other implementations of the releasable adhesive 423 may include a non-permanent adhesive material, a thermolabile material, or a photolabile material.

In this example, a first die 403a and a second die 403b are attached to the sacrificial layer 445 in an area for the microelectronic device 400. Additional instances of the first die 403a and the second die 403b may be attached to the sacrificial layer 445 in separate areas for additional microelectronic devices 400a, as depicted in FIG. 4A. Either of the first die 403a and the second die 403b may be manifested as an integrated circuit, a discrete semiconductor component, an electro-optical device, a MEMS device, or other microelectronic die. The first die 403a and the second die 403b may be separate types of devices.

FIG. 4B shows the microelectronic device 400 in more detail. In this example, the first die 403a and the second die 403b may be attached to the sacrificial layer 445 by a die attach material 404, or by another material or method. In this example, the die attach material 404 may be electrically non-conductive, to isolate the first die 403a and the second die 403b. The die attach material 404 may be implemented as an adhesive such as epoxy, to provide a desired level of electrical isolation. The first die 403a and the second die 403b may have terminals 405 for electrical connections to components in the first die 403a and the second die 403b. The terminals 405 may be manifested as bond pads, or circuit nodes. The terminals 405 may include materials suitable for wire bonding.

Ribbon stitch bond strips 446 are formed of ribbon wire on the sacrificial layer 445 adjacent to the first die 403a and the second die 403b, using a ribbon bond wire bonding process. The ribbon stitch bond strips 446 provide initial portions of intermediate pads 407 of the microelectronic device 400. Multiple ribbon stitch bond strips 446 may be formed in each of the intermediate pads 407, to provide mechanical support for subsequently-formed package leads 421, shown in FIG. 4J. Referring back to FIG. 4B, the ribbon stitch bond strips 446 in each intermediate pad 407 may be formed to contact each other, or may be separated by a few microns. The sacrificial layer 445 may facilitate forming the ribbon stitch bond strips 446 by providing a suitable surface for ribbon stitch bonding, to which the ribbon wire adheres.

FIG. 4C depicts example configurations of the ribbon stitch bond strips 446 in the intermediate pads 407 of FIG. 4B. A first intermediate pad 407a may have a parallel non-contacting configuration, with ribbon stitch bond strips 446 arranged in parallel. Adjacent ribbon stitch bond strips 446 in the first intermediate pad 407a may be separated by a lateral space that is sufficiently narrow, so that subsequently-plated metal on the adjacent ribbon stitch bond strips 446 in the first intermediate pad 407a merges together to form a metal pad that is continuous across all the ribbon stitch bond strips 446 in the first intermediate pad 407a. The first intermediate pad 407a may have a minimum lateral dimension 408 of 50 microns to 300 microns. The term “lateral” refers to a direction parallel to a face of the sacrificial layer 445 on which the ribbon stitch bond strips 446 are formed. The minimum lateral dimension 408 may be selected provide a sufficient area for subsequent attachment of the package leads 421, shown in FIG. 4J.

Referring back to FIG. 4C, a second intermediate pad 407b may have a crossed parallel configuration, with first ribbon stitch bond strips 446a formed parallel to each other, and second ribbon stitch bond strips 446b formed parallel to each other and perpendicular to the first ribbon stitch bond strips 446a. Each of the first ribbon stitch bond strips 446a may contact each of the second ribbon stitch bond strips 446b. The first ribbon stitch bond strips 446a and the second ribbon stitch bond strips 446b may be formed with open spaces between the first ribbon stitch bond strips 446a and the second ribbon stitch bond strips 446b, as indicated in FIG. 4C. Adjacent instances of the first ribbon stitch bond strips 446a and the second ribbon stitch bond strips 446b may be formed sufficiently close to each other so that subsequently-plated metal on the adjacent first ribbon stitch bond strips 446a and the adjacent second ribbon stitch bond strips 446b in the second intermediate pad 407b merges together to form a metal pad that is continuous across all the first ribbon stitch bond strips 446a and the second ribbon stitch bond strips 446b in the first ribbon stitch bond strips 446a and the second ribbon stitch bond strips 446b. The second intermediate pad 407b may have a minimum lateral dimension 408 of 50 microns to 300 microns, to provide a sufficient area for subsequent attachment of the package leads 421.

A third intermediate pad 407c may have a parallel contacting configuration, with ribbon stitch bond strips 446 arranged in parallel. Adjacent ribbon stitch bond strips 446 in the third intermediate pad 407c may be formed so as to contact each other, as indicated in FIG. 4C. The third intermediate pad 407c may have a minimum lateral dimension 408 of 50 microns to 300 microns, to provide a sufficient area for subsequent attachment of the package leads 421. The third intermediate pad 407c may have an elongated shape, with a length significantly longer than the minimum lateral dimension 408, to provide lower resistance through the third intermediate pad 407c. The elongated shape of the third intermediate pad 407c may be appropriate for power and ground connections to the microelectronic device 400 of FIG. 4B, which commonly conduct significantly more current than signal connections.

Referring to FIG. 4D, wire bonds 409 are formed by a wire bonding process to connect the first die 403a and the second die 403b to the ribbon stitch bond strips 446 of the intermediate pads 407. Optionally, one or more of the wire bonds 409 may be formed so as to connect the first die 403a to the second die 403b, as indicated in FIG. 4D. FIG. 4D depicts the wire bonds 409 as formed using ribbon bond wire. Other types of bond wire, such as round bond wire, are within the scope of this example. The wire bonds 409 may include, for example, copper wire, coated copper wire, gold wire, or aluminum wire.

Referring to FIG. 4E, an encapsulation material 410 is formed over the first die 403a and the second die 403b, the wire bonds 409, and the ribbon stitch bond strips 446. The encapsulation material 410 contacts the ribbon stitch bond strips 446. The encapsulation material 410 may include epoxy or other material suitable for protecting the first die 403a and the second die 403b, the wire bonds 409, and the ribbon stitch bond strips 446 from moisture and contamination. Fill particles 447 may be distributed in the encapsulation material 410. In one version of this example, the fill particles 447 may have a thermal expansion coefficient between an average thermal expansion coefficient of the first die 403a and the second die 403b, and a thermal expansion coefficient of a circuit board on which the microelectronic device 400 will be mounted, which may provide improved mechanical reliability, compared to a similar device with no fill particles 447 in the encapsulation material 410. In another version of this example, the fill particles 447 may have a thermal conductivity higher than a thermal conductivity of the encapsulation material 410, which may provide a reduced operating temperature for the first die 403a and the second die 403b, and thus improved reliability, compared to a similar device with no fill particles 447 in the encapsulation material 410.

Referring to FIG. 4F, the carrier 401 and the releasable adhesive 423 are removed from the microelectronic device 400, leaving the sacrificial layer 445 attached to the microelectronic device 400. In versions of this example in which the releasable adhesive 423 is implemented having the microsuction tape or the silicone layer, described in reference to FIG. 4A, the carrier 401 and the releasable adhesive 423 may be removed by a peeling process, as indicated in FIG. 4F. In versions of this example in which the releasable adhesive 423 is implemented with photolabile material or thermolabile material, the releasable adhesive 423 may be weakened, for example by exposure to light in a prescribed wavelength band or by heating to a prescribed temperature, as appropriate, to facilitate removal of the carrier 401.

Referring to FIG. 4G, the sacrificial layer 445 is removed from the microelectronic device 400, exposing the ribbon stitch bond strips 446. The sacrificial layer 445 may be removed using a wet etch bath 448 which etches the sacrificial layer 445 without significantly degrading the microelectronic device 400. For example, the wet etch bath 448 may include an aqueous solution of potassium hydroxide, tetramethylammonium hydroxide, or choline hydroxide, which may remove aluminum oxide, aluminum nitride, polycrystalline silicon, hydrogen-rich silicon nitride, or PSG in the sacrificial layer 445 without significantly degrading copper or gold in the ribbon stitch bond strips 446. FIG. 4G depicts removal of the sacrificial layer 445 partway to completion.

Referring to FIG. 4H, a plating process using at least one plating bath 415 forms one or more plated metal layers of the intermediate pads 407 on the ribbon stitch bond strips 446 where exposed by the encapsulation material 410. The one or more plated metal layers may include a base layer 416 on the ribbon stitch bond strips 446, and a barrier layer 417 on the base layer 416. The chemistry of the plating bath 415 may be changed to provide desired compositions of the one or more plated metal layers. The plating process may be implemented as an autocatalytic electroless process or an immersion process, for example. The base layer 416 may include a metal, such as copper, with a high electrical conductivity, and may be formed to be 50 microns to 150 microns thick, to provide a low resistance for the intermediate pads 407, and to connect the ribbon stitch bond strips 446 in each of the intermediate pads 407. The barrier layer 417 may include one or more metals that provide a surface appropriate for subsequently attaching package leads 421, shown in FIG. 4J. Referring back to FIG. 4H, the barrier layer 417 may include, for example, nickel, palladium, or platinum. The barrier layer 417 may be formed to be 10 microns to 40 microns thick, for example. The base layer 416 and the barrier layer 417 may be characterized by a conformal configuration on the ribbon stitch bond strips 446, in which the base layer 416 and the barrier layer 417 conform to contours of the ribbon stitch bond strips 446, resulting from the plating process. The base layer 416 and the barrier layer 417 are parts of the intermediate pads 407, along with the ribbon stitch bond strips 446, in this example. All the elements of the intermediate pads 407, that is, the ribbon stitch bond strips 446, the base layer 416, and the barrier layer 417, are formed without using a photolithographic process, which may advantageously reduce fabrication cost and fabrication complexity of the microelectronic device 400.

Referring to FIG. 4I, the microelectronic device 400 is singulated to separate the microelectronic device 400 from the additional microelectronic devices 400a of FIG. 4A. The microelectronic device 400 may be singulated using a saw process, a laser ablation process, or other method. Singulation may be facilitated by an absence of metal in the encapsulation material 410 between the microelectronic device 400 and the adjacent additional microelectronic devices 400a.

Package leads 421 are attached to the intermediate pads 407. The package leads 421 may be attached to the intermediate pads 407, for example, by a welding process, by a solder process, or by applying electrically conductive adhesive to the intermediate pads 407. The package leads 421 may be parts of a lead frame, not shown in FIG. 4I, while the package leads 421 are attached to the intermediate pads 407. The package leads 421 may be formed before the package leads 421 are attached to the intermediate pads 407, or after the package leads 421 are attached to the intermediate pads 407. The package leads 421 are shaped to provide a desired package format for the microelectronic device 400. The package leads 421 may be shaped as disclosed in reference to the package leads 121 of FIG. 1K. The package leads 421 may be shaped so as to provide a leaded package format for the microelectronic device 400, as depicted in FIG. 4I, or may be shaped so as to provide a leadless package format.

Referring to FIG. 4J, an external component 449 is attached to the package leads 421. The external component 449 may be implemented as any of an integrated circuit, a discrete semiconductor component, an electro-optical device, a MEMS device, or a passive component, such as a resistor, a capacitor, an inductor, or a filter. The external component 449 may have external terminals 450 connected to one or more components in the external component 449. A die connection material 451 is used to connect the external terminals 450 to the package leads 421. The die connection material 451 may be implemented as a solder, an electrically conductive adhesive, or an anisotropic conductive tape, for example. In this example, the external component 449 is part of the microelectronic device 400.

FIG. 4K shows the completed microelectronic device 400. Having the external component 449 attached to the package leads 421 may reduce an area of the microelectronic device 400, advantageously enabling a smaller form factor for a product using the microelectronic device 400. Having the external component 449 attached to the package leads 421 may provide lower resistance connections between the external component 449 and the first die 403a or the second die 403b, compared to locating the external device on a circuit substrate adjacent to the first die 403a or the second die 403b.

Various features of the examples disclosed herein may be combined in other manifestations of example microelectronic devices. For example, multiple die may be included in the example microelectronic devices disclosed in reference to FIG. 1A through FIG. 1L, FIG. 2A through FIG. 2K, and FIG. 3A through FIG. 3L, similar to the example disclosed in reference to FIG. 4A through FIG. 4K. Encapsulation material may be formed on the example microelectronic devices disclosed in the examples herein by any of the methods disclosed in reference to FIG. 1A through FIG. 1L, FIG. 2A through FIG. 2K, FIG. 3A through FIG. 3L, and FIG. 4A through FIG. 4K. Singulation may be performed by any of the methods disclosed in reference to FIG. 1A through FIG. 1L, FIG. 2A through FIG. 2K, and FIG. 3A through FIG. 3L. Device identification marks may be formed on the microelectronic devices at any stage of formation, and formation of the device identification marks is not limited to specific steps disclosed in reference to FIG. 1A through FIG. 1L. Package leads may be formed on the example microelectronic devices disclosed in the examples herein by any of the methods disclosed in reference to FIG. 1A through FIG. 1L, FIG. 2A through FIG. 2K, FIG. 3A through FIG. 3L, and FIG. 4A through FIG. 4K. Elements of the example microelectronic devices described herein, such as the intermediate pads, the wire bonds, the encapsulation material, may be formed according to methods disclosed with regard to analogous elements in the following commonly assigned U.S. patent applications: U.S. patent application Ser. No. 12/______, Attorney Docket Number TI-78741, filed concurrently with this application, U.S. patent application Ser. No. 12/______, Attorney Docket Number TI-78742, filed concurrently with this application, and U.S. patent application Ser. No. 12/______, Attorney Docket Number TI-78745, filed concurrently with this application. These commonly assigned U.S. patent applications are incorporated herein by reference but are not admitted to be prior art with respect to the present invention by their mention in this section.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a die;
intermediate pads, wherein the intermediate pads are free of photolithographically-defined structures;
wire bonds connecting the die to the intermediate pads;
an encapsulation material surrounding the wire bonds, at least partially surrounding the die and contacting the die, and contacting the intermediate pads; and
package leads contacting the intermediate pads, the package leads being located outside of the encapsulation material.

2. The microelectronic device of claim 1, wherein each of the intermediate pads includes a plurality of wire stud bonds.

3. The microelectronic device of claim 1, wherein each of the intermediate pads includes plated metal, wherein the plated metal conforms to contours of electrically conductive elements of the intermediate pads contacting the plated metal.

4. The microelectronic device of claim 1, wherein each of the intermediate pads includes a preformed metal pad.

5. The microelectronic device of claim 1, wherein each of the intermediate pads includes a supplementary metal pad, wherein the supplementary metal pad is continuous across the intermediate pad containing the supplementary metal pad.

6. The microelectronic device of claim 1, wherein each of the intermediate pads includes a plurality of ribbon stitch bond strips.

7. The microelectronic device of claim 1, further including fill particles distributed in the encapsulation material, wherein the fill particles have a thermal expansion coefficient higher than a thermal expansion coefficient of the die.

8. The microelectronic device of claim 1, further including fill particles distributed in the encapsulation material, wherein the fill particles have a thermal conductivity higher than a thermal conductivity of the encapsulation material.

9. The microelectronic device of claim 1, wherein the microelectronic device is free of electrically conductive leads extending to lateral surfaces of the encapsulation material, the lateral surfaces being perpendicular to a surface of the encapsulation material contacting the intermediate pads.

10. The microelectronic device of claim 1, further including an external component attached to at least one of the package leads, wherein the external component is located outside of the encapsulation material.

11. A method of forming a microelectronic device, comprising:
acquiring a carrier;
disposing a first die on the carrier;
forming at least portions of intermediate pads on the carrier, by a method free of a photolithographic process;
forming wire bonds between the first die and the at least portions of the intermediate pads;
forming an encapsulation material over the first die and the wire bonds, wherein the encapsulation material contacts the at least portions of the intermediate pads;
removing the carrier, wherein the at least portions of the intermediate pads are exposed at a surface of the encapsulation material; and
forming package leads on the intermediate pads, the package leads being located outside of the encapsulation material.

12. The method of claim 11, wherein forming the at least portions of the intermediate pads includes forming a plurality of wire stud bonds on the carrier.

13. The method of claim 11, further including plating metal on the at least portions of the intermediate pads after removing the carrier.

14. The method of claim 11, wherein a releasable adhesive is disposed on the carrier prior to disposing the first die on the carrier.

15. The method of claim 14, wherein the releasable adhesive includes a material selected from the group consisting of a photolabile material and a thermolabile material.

16. The method of claim 11, wherein:
a pad metal layer is disposed on the carrier prior to forming the wire bonds; and
removing the carrier includes removing a portion of the pad metal layer, wherein portions of the pad metal layer contacting the at least portions of the intermediate pads remain attached to the at least portions of the intermediate pads.

17. The method of claim 11, further including plating metal on the at least portions of the intermediate pads after removing the carrier.

18. The method of claim 11, wherein forming the package leads on the intermediate pads includes a welding process.

19. The method of claim 11, wherein forming the package leads on the intermediate pads includes a solder process.

20. The method of claim 19, wherein the solder process uses a solder anisotropic conductive film.
